(19) United States
(12) Patent Application Publication
(10) Pub. No.: US 2018/0231376 A1
(43) Pub. Date: Aug. 16, 2018

(54) DETECTOR FOR AN OPTICAL DETECTION OF AT LEAST ONE OBJECT

(71) Applicant: trinamiX GmbH, Ludwigshafen am Rhein (DE)

(72) Inventors: Robert SEND, Karlsruhe (DE); Ingmar BURDER, Neuleiningen (DE); Christoph LUNGENSCHMIED, Mannheim (DE)

(73) Assignee: trinamiX GmbH, Ludwigshafen am Rhein (DE)

(21) Appl. No.: 15/751,283

(22) PCT Filed: Aug. 10, 2016
(86) PCT No.: PCT/EP2016/069049

§ 371 Date: Feb. 8, 2018

(30) Foreign Application Priority Data
Aug. 10, 2015 (EP) 15180354.1

(51) Int. Cl. G01C 3/08; G01S 3/781; G01S 3/786; G01S 17/46; G01S 7/481; H01L 27/30; H01L 51/42; H01L 51/44

(52) U.S. Cl. CPC G01C 3/08; G01S 3/781; G01S 3/786; G01S 17/46; H01L 51/0037; H01L 27/307; H01L 51/4273; H01L 51/442; G01S 7/4816

(57) ABSTRACT

Disclosed herein is a detector (110) for an optical detection of at least one object (112) the detector (110) including: (a) at least one longitudinal optical sensor (114) having at least one sensor region (130), the longitudinal optical sensor (114) containing at least one photodiode (134) the photodiode (134) having at least two electrodes (166, 174), wherein at least one photoactive layer (180) containing at least one electron donor material and at least one electron acceptor material is embedded between the electrodes (166, 174); and (b) at least one evaluation device (150) designed to generate at least one item of information on a longitudinal position of the object (112) by evaluating the longitudinal sensor signal. The detector (110) is efficient for accurately determining of a position of at least one object (112) in space, and exhibits an FiP effect with an improved signal-to-noise ratio.

### FIELD OF THE INVENTION

The invention relates to a detector for an optical detection of at least one object, in particular, for determining a position of at least one object, specifically with regard to a depth or both to the depth and a width of the at least one object. Furthermore, the invention relates to a human-machine interface, an entertainment device, a scanning device, a tracking system and a camera. Further, the invention relates to a method for optical detection of at least one object and to various uses of the detector. Such devices, methods and uses can be employed for example in various areas of daily life, gaming, traffic technology, mapping of spaces, production technology, security technology, medical technology or in the sciences. However, further applications are possible.

### PRIOR ART

Various detectors for optically detecting at least one object are known on the basis of optical detectors. WO 2012/110924 A1 discloses an optical detector comprising at least one optical sensor which exhibits at least one sensor region. Herein, the optical sensor is designed to generate at least one sensor signal in a manner dependent on an illumination of the sensor region. According to the so-called “FiP effect”, the sensor signal, given the same total power of the illumination, is hereby dependent on a geometry of the illumination, in particular on a beam cross-section of the illumination on the sensor area The detector furthermore has at least one evaluation device designated to generate at least one item of geometrical information from the sensor signal, in particular at least one item of geometrical information about the illumination and/or the object.

The optical sensors as exemplary disclosed in WO 2012/110924 A1 are selected from the group consisting of an organic solar cell, a dye solar cell, and a dye-sensitized solar cell (DSC), preferably a solid-state dye-sensitized solar cell (ssDSC). Herein, a DSC generally refers to a setup having at least two electrodes, wherein at least one of the electrodes is at least partially transparent, wherein at least one n-semiconducting metal oxide, at least one dye and at least one electrolyte or p-semiconducting material is embedded between the electrodes. In this kind of optical sensors, the sensor signal may be provided in form of an ac photocurrent which is enhanced when modulated light is focused onto the sensor area.

WO 2014/097181 A1 discloses a method and a detector for determining a position of at least one object, by using at least one transversal optical sensor and at least one longitudinal optical sensor. Preferably, a stack of longitudinal optical sensors, exemplary selected from the group consisting of an organic solar cell, a dye solar cell, and a dye-sensitized solar cell (DSC), preferably a solid-state dye-sensitized solar cell (ssDSC), is employed, in particular to determine a longitudinal position of the object with a high degree of accuracy and without ambiguity. In general, at least two individual “FiP sensors”, i.e. a optical sensors based on the FiP-effect, are required in order to determine the longitudinal position of the object without ambiguity, wherein at least one of the FiP sensors is employed for normalizing the longitudinal sensor signal for taking into account possible variations of the illumination power. Further, WO 2014/097181 A1 discloses a human-machine interface, an entertainment device, a tracking system, and a camera, each comprising at least one such detector for determining a position of at least one object.

S. Günes and N. S. Sariciftci, Inorganica Chimica Acta 361, 2008, p. 581-588, present a review about hybrid solar cells. As used therein, the “hybrid solar cells” comprise a combination of both organic and inorganic materials which combines the properties of inorganic semiconductors with the film forming properties of the conjugated polymers. While organic materials are inexpensive, easily processable and their functionality can be tailored by molecular design and chemical synthesis, inorganic semiconductors can be manufactured as nanoparticles which offer an advantage of having high absorption coefficients and size tunability. By varying the size of the nanoparticles, an absorption range can be tailored.

L. Biana, E. Zhua, J. Tanga, W. Tanga, and F. Zhang, Progress in Polymer Science 37, 2012, p. 1292-1331, provide a review about conjugated polymers for organic photovoltaic (OPV) cells. Herein, they describe that polymer solar cells (PSCs) have emerged as an alternative photovoltaic technology, in particular, due to a potential of cost-effective production of large-area flexible devices by using solution-processing techniques. Typically, PSCs adopt a bulk-heterojunction (BJH) architecture, in which a photoactive layer is cast from a mixture solution of a donor polymer and a soluble fullerene-based electron acceptor, such as [6,6]phenyl C61 butyric acid methyl ester (PC60BM) or [6,6]-phenyl-C71-butyric acid methyl ester (PC71BM), and sandwiched between two electrodes. Accordingly, a typical BHJ solar cell comprises an indium tin oxide (ITO) coated glass substrate, covered by a layer of a transparent conductive polymer, usually polyethylenedioxythiophene:polystyrene sulphonate (PEDOT:PSS). A mixture comprising the donor polymer and a fullerene derivative is placed on the top of the PEDOT:PSS layer, and a thin layer of a metal, preferably aluminum (Al) or silver (Ag), is deposited on the photoactive layer as cathode. Herein, the donor polymer serves as a main solar light absorber and as a hole transporting layer, whereas the small molecule is adapted to transport electrons.

Whereas fullerenes are usually employed as acceptor materials in BHJ OPVs, non-fullerene molecular acceptors are also known. A. Facchetti, Materials Today, Vol. 16, No. 4, 2013, p. 123-132, reviews polymer donor-polymer acceptor (all-polymer) BHJ OPVs, in which an n-type semiconducting polymer is employed as the electron acceptor instead of a fullerene or another small molecule. This kind of BHJ OPVs exhibit a number of advantages, in particular, high absorption coefficients in the visible and near-infrared spectral regions, a more efficient tuning of energy levels, and an increased flexibility in controlling solution viscosity. Further, photoactive blend compositions are provided herein, wherein each composition comprises a selected donor polymer and a selected acceptor polymer.

Despite the advantages as implied by the above-mentioned devices and detectors, specifically by the detectors as disclosed in WO 2012/110924 A1 and in WO 2014/097181 A1, there still is a need for improvements, in particular with respect to a simple, cost-efficient and, still, reliable spatial detector.

Especially, a production of optical sensors comprising one of an organic solar cell, a dye solar cell, a dye-sensitized solar cell (DSC), preferably a solid-state dye-sensitized solar cell (ssDSC), requires considerable amounts of time and energy which is, particularly, due to at least one high-temperature sintering step applied during their production.

### PROBLEM ADDRESSED BY THE INVENTION

Therefore, a problem addressed by the present invention is that of specifying a device and a method for optically detecting at least one object which at least substantially avoid the disadvantages of known devices and methods of this type. In particular, an improved simple, cost-efficient and, still, reliable spatial detector for determining the position of an object in space would be desirable.

More particular, the problem addressed by the present invention is that of providing an optical detector comprising a material within the sensor region which, on one hand, may exhibit the FiP effect with an improved signal-to-noise ratio but which, on the other hand, may be produced in a less time- and energy-consuming manner.

### SUMMARY OF THE INVENTION

This problem is solved by the invention with the features of the independent patent claims. Advantageous developments of the invention, which can be realized individually or in combination, are presented in the dependent claims and/or in the following specification and detailed embodiments.

As used herein, the expressions “have”, “comprise” and “contain” as well as grammatical variations thereof are used in a non-exclusive way. Thus, the expression “A has B” as well as the expression “A comprises B” or “A contains B” may both refer to the fact that, besides B, A contains one or more further components and/or constituents, and to the case in which, besides B, no other components, constituents or elements are present in A.

In a first aspect of the present invention, a detector for optical detection, in particular, for determining a position of at least one object, specifically with regard to a depth or to both the depth and a width of the at least one object is disclosed.

The “object” generally may be an arbitrary object, chosen from a living object and a non-living object. Thus, as an example, the at least one object may comprise one or more articles and/or one or more parts of an article. Additionally or alternatively, the object may be or may comprise one or more living beings and/or one or more parts thereof, such as one or more body parts of a human being, e.g. a user, and/or an animal.

As used herein, a “position” generally refers to an arbitrary item of information on a location and/or orientation of the object in space. For this purpose, as an example, one or more coordinate systems may be used, and the position of the object may be determined by using one, two, three or more coordinates. As an example, one or more Cartesian coordinate systems and/or other types of coordinate systems may be used. In one example, the coordinate system may be a coordinate system of the detector in which the detector has a predetermined position and/or orientation. As will be outlined in further detail below, the detector may have an optical axis, which may constitute a main direction of view of the detector. The optical axis may form an axis of the coordinate system, such as a z-axis. Further, one or more additional axes may be provided, preferably perpendicular to the z-axis.

Thus, as an example, the detector may constitute a coordinate system in which the optical axis forms the z-axis and in which, additionally, an x-axis and a y-axis may be provided which are perpendicular to the z-axis and which are perpendicular to each other. As an example, the detector and/or a part of the detector may rest at a specific point in this coordinate system, such as at the origin of this coordinate system. In this coordinate system, a direction parallel or antiparallel to the z-axis may be regarded as a longitudinal direction, and a coordinate along the z-axis may be considered a longitudinal coordinate. An arbitrary direction perpendicular to the longitudinal direction may be considered a transversal direction, and an x- and/or y-coordinate may be considered a transversal coordinate.

Alternatively, other types of coordinate systems may be used. Thus, as an example, a polar coordinate system may be used in which the optical axis forms a z-axis and in which a distance from the z-axis and a polar angle may be used as additional coordinates. Again, a direction parallel or antiparallel to the z-axis may be considered a longitudinal direction, and a coordinate along the z-axis may be considered a longitudinal coordinate. Any direction perpendicular to the z-axis may be considered a transversal direction, and the polar coordinate and/or the polar angle may be considered a transversal coordinate.

As used herein, the detector for optical detection generally is a device which is adapted for providing at least one item of information on the position of the at least one object. The detector may be a stationary device or a mobile device. Further, the detector may be a stand-alone device or may form part of another device, such as a computer, a vehicle or any other device. Further, the detector may be a hand-held device. Other embodiments of the detector are feasible.

The detector may be adapted to provide the at least one item of information on the position of the at least one object in any feasible way. Thus, the information may e.g. be provided electronically, visually, acoustically or in any arbitrary combination thereof. The information may further be stored in a data storage of the detector or a separate device and/or may be provided via at least one interface, such as a wireless interface and/or a wire-bound interface.

The detector for an optical detection of at least one object according to the present invention comprises:
at least one longitudinal optical sensor, wherein the longitudinal optical sensor has at least one sensor region, wherein the longitudinal optical sensor is designed to generate at least one longitudinal sensor signal in a manner dependent on an illumination of the sensor region by the light beam, wherein the longitudinal sensor signal, given the same total power of the illumination, is dependent on a beam cross-section of the light beam in the sensor region, wherein the longitudinal optical sensor comprises at least one photodiode, the photodiode having at least two electrodes, wherein at least one photoactive layer comprising at least one electron donor material and at least one electron acceptor material is embedded between the electrodes; and
at least one evaluation device, wherein the evaluation device is designed to generate at least one item of information on a longitudinal position of the object by evaluating the longitudinal sensor signal.

Herein, the components listed above may be separate components. Alternatively, two or more of the components as listed above may be integrated into one component. Further, the at least one evaluation device may be formed as a separate evaluation device independent from the longitudinal optical sensor, but may preferably be connected to the longitudinal optical sensor in order to receive the longitudinal sensor signal. Alternatively, the at least one evaluation device may fully or partially be integrated into the longitudinal optical sensor.

The detector according to the present invention comprises at least one longitudinal optical sensor. Herein, the longitudinal optical sensor has at least one sensor region, i.e. an area within the longitudinal optical sensor being sensitive to an illumination by an incident light beam. As used herein, the “longitudinal optical sensor” is generally a device which is designed to generate at least one longitudinal sensor signal in a manner dependent on an illumination of the sensor region by the light beam, wherein the longitudinal sensor signal, given the same total power of the illumination, is dependent, according to the so-called “FiP effect” on a beam cross-section of the light beam in the sensor region. The longitudinal sensor signal may, thus, generally be an arbitrary signal indicative of the longitudinal position, which may also be denoted as a depth. As an example, the longitudinal sensor signal may be or may comprise a digital and/or an analog signal. As an example, the longitudinal sensor signal may be or may comprise a voltage signal and/or a current signal. Additionally or alternatively, the longitudinal sensor signal may be or may comprise digital data. The longitudinal sensor signal may comprise a single signal value and/or a series of signal values. The longitudinal sensor signal may further comprise an arbitrary signal which is derived by combining two or more individual signals, such as by averaging two or more signals and/or by forming a quotient of two or more signals.

Specifically, the FiP effect is observed here in at least one photodiode, the photodiode having at least two electrodes, wherein at least one photoactive layer comprising at least one electron donor material and at least one electron acceptor material is embedded between the electrodes. As generally used, the term “photodiode” relates to a device being capable of converting a fraction of incident light into an electrical current. With particular regard to the present invention, the photodiode as used here, exhibits the above-described FiP effect. Thus, the at least one longitudinal optical sensor may comprise at least one organic electron donor material and/or at least one organic electron acceptor material. Besides the at least one organic material, one or more further materials may be comprised, which may be selected from organic materials or inorganic materials. Thus, the optical detector may be designed as an all-organic optical detector comprising organic materials only, or as a hybrid detector comprising one or more organic materials and one or more inorganic materials. Still, other embodiments are feasible.

In a preferred embodiment, the photoactive layer used in the optical detector according to the present invention has, on one hand, at least one electron donor material comprising a donor polymer, in particular an organic donor polymer, and, on the other hand, at least one electron acceptor material, in particular, an acceptor small-molecule, preferably selected from the group comprising a fullerene-based electron acceptor material, tetracyanoquinodimethane (TCNQ), a perylene derivate, an acceptor polymer, and inorganic nanocrystals.

In a preferred embodiment, the electron donor material may, thus, comprise a donor polymer while the electron acceptor material may comprise an acceptor polymer, thus providing a basis for an all-polymer photoactive layer. In a particular embodiment, a copolymer may, simultaneously, be constituted in a manner that it may comprise a donor polymer unit and an acceptor polymer unit and may, therefore, also be denominated as a “push-pull copolymer” based on the respective functions of each of the units of the copolymer. As used herein, the term “photoactive layer” is related to a material, in particular to an organic material, within the photodiode as comprised by the optical sensor according to the present invention, wherein the material is susceptible to an influence of the incident light beam, in particular, in a manner that it may exhibit the FiP effect. Accordingly, the sensor signal as provided by the photodiode may, thus, be in form of an alternating current (ac) photocurrent which is enhanced when the incident light beam, in particular a modulated incident light beam, is focused onto the photodiode which constitutes at least a part of the sensor area.

Preferably, the electron donor material and the electron acceptor material may be comprised within the photoactive layer in form of a mixture. As generally used, the term “mixture” relates to a blend of two or more individual compounds, wherein the individual compounds within the mixture maintain their chemical identity. In a particularly preferred embodiment, the mixture employed in the photoactive layer according to the present invention may comprise the electron donor material and the electron acceptor material in a ratio from 1:100 to 100:1, more preferred from 1:10 to 10:1, in particular in a ratio of from 1:2 to 2:1, such as 1:1. However, other ratios of the respective compounds may also be applicable, in particular depending on the kind and number of individual compounds being involved. Preferably, the electron donor material and the electron acceptor material as comprised in form of the mixture within the photoactive layer may constitute an interpenetrating network of donor and acceptor domains, wherein interfacial areas between the donor and acceptor domains may be present, and wherein percolation pathways may connect the domains to the electrodes. In particular, the donor domains may, thus, connect the electrode which assumes a function of a hole extracting contact while the acceptor domains may, thus, contact the electrode which assumes the function of an electron extracting contact.

As used herein, the term “donor domain” refers to a region within the photoactive layer in which the electron donor material may predominantly, particularly completely, be present. Similarly, the term “acceptor domain” refers to a region within the photoactive layer in which the electron acceptor material may predominantly, in particular completely, be present. Herein, the domains may exhibit areas, which are denominated as the “interfacial areas”, which allow a direct contact between the different kinds of regions. Further, the term “percolation pathways” refers to conductive paths within the photoactive layer along which a transport of electrons or holes, respectively, may predominantly take place.

As mentioned above, the at least one electron donor material may, preferably, comprise a donor polymer, in particular an organic donor polymer. As used herein, the term “polymer” refers to a macromolecular composition generally comprising a large number of molecular repeat units which are usually denominated as “monomers” or “monomeric units”. For the purposes of the present invention, however, a synthetic organic polymer may be preferred. Within this regard, the term “organic polymer” refers to the nature of the monomeric units which may, generally, be attributed as organic chemical compounds. As used herein, the term “donor polymer” refers to a polymer which may particularly be adapted to provide electrons as the electron donor material.

Preferably, the donor polymer may comprise a conjugated system, in which delocalized electrons may be distributed over a group of atoms being bonded together by alternating single and multiple bonds, wherein the conjugated system may be one or more of cyclic, acyclic, and linear. Thus, the organic donor polymer may, preferably, be selected from one or more of the following polymers:
poly[3-hexylthiophene-2,5.diyl] (P3HT),
poly[3-(4-n-octyl)-phenylthiophene] (POPT),
poly[3-10-n-octyl-3-phenothiazine-vinylenethiophene-co-2,5-thiophene] (PTZV-PT), poly[4,8-bis[(2-ethylhexyl)oxy]benzo[1,2-b:4,5-b]dithiophene-2,6-diyl][3-fluoro-2-[(2-ethylhexyl)carbonyl]thieno[3,4-b]thiophenediyl] (PTB7),
poly[thiophene-2,5-diyl-alt-[5,6-bis(dodecyloxy)benzo[c][1,2,5]thiadiazole]-4,7-diyl] (PBT-T1),
poly[2,6-(4,4-bis-(2-ethylhexyl)-4H-cyclopenta[2,1-b;3,4-b]dithiophene)-alt-4,7(2,1,3-benzothiadiazole)] (PCPDTBT),
poly[5,7-bis(4-decanyl-2-thienyl)-thieno(3,4-b)diathiazolethiophene-2,5] (PDDTT),
poly[N-9′-heptadecanyl-2,7-carbazole-alt-5,5-(4′,7′-di-2-thienyl-2′,1′,3′-benzothiadiazole)] (PCDTBT), or
poly[(4,4′-bis(2-ethylhexyl)dithieno[3,2-b;2′,3′-d]silole)-2,6-diyl-alt-(2,1,3-benzothia-diazole)-4,7-diyl] (PSBTBT),
poly[3-phenylhydrazone thiophene] (PPHT),
poly[2-methoxy-5-(2-ethylhexyloxy)-1,4-phenylenevinylene] (MEH-PPV),
poly[2-methoxy-5-(2′-ethylhexyloxy)-1,4-phenylene-1,2-ethenylene-2,5-dimethoxy-1,4-phenylene-1,2-ethenylene] (M3EH-PPV),
poly[2-methoxy-5-(3′,7′-dimethyloctyloxy)-1,4-phenylenevinylene] (MDMO-PPV),
poly[9,9-di-octylfluorene-co-bis-N,N-4-butylphenyl-bis-N,N-phenyl-1,4-phenylenediamine] (PFB), or a derivative, a modification, or a mixture thereof.

However, other kinds of donor polymers or further electron donor materials may also be suitable, in particular polymers which are sensitive in the infrared spectral range, especially in the near infrared range above 1000 nm, preferably diketopyrrolopyrrol polymers, in particular, the polymers as described in EP 2 818 493 Al, more preferably the polymers denoted as “P-1” to “P-10” therein; benzodithiophene polymers as disclosed in WO 2014/086722 A1, especially diketopyrrolopyrrol polymers comprising benzodithiophene units; dithienobenzofuran polymers according to US 2015/0132887 A1, especially dithienobenzofuran polymers comprising diketo-pyrrolopyrrol units; phenantro[9, 10-B]furan polymers as described in US 2015/0111337 A1, especially phenantro[9, 10-B]furan polymers which comprise diketopyrrolopyrrol units; and polymer compositions comprising diketopyrrolopyrrol oligomers, in particular, in an oligomer-polymer ratio of 1:10 or 1:100, such as disclosed in US 2014/0217329 A1.

As further mentioned above, the electron acceptor material may, preferably, comprise a fullerene-based electron acceptor material. As generally used, the term “fullerenes” refers to cage-like molecules of pure carbon, including Buckminster fullerene (C60) and the related spherical fullerenes. In principle, the fullerenes in the range of from C20 to C2000 may be used, the range C60 to C96 being preferred, particularly C60, C70 and C84. Mostly preferred are fullerenes which are chemically modified, in particular one or more of:
[6,6]-phenyl-C61-butyric acid methyl ester (PC60BM),
[6,6]-Phenyl-C71-butyric acid methyl ester (PC70BM),
[6,6]-phenyl C84 butyric acid methyl ester (PC84BM), or
an indene-C60 bisadduct (ICBA),

but also dimers comprising one or two C60 or C70 moieties, in particular
a diphenylmethanofullerene (DPM) moiety comprising one attached oligoether (OE) chain (C70-DPM-OE), or
a diphenylmethanofullerene (DPM) moiety comprising two attached oligoether (OE) chains (C70-DPM-OE2),

or a derivative, a modification, or a mixture thereof. However, TCNQ, or a perylene derivative may also be suitable.

Alternatively or in addition, the electron acceptor material may, preferably, comprise inorganic nanocrystals, in particular, selected from cadmium selenide (CdSe), cadmium sulfide (CdS), copper indium sulfite (CuInS₂), or lead sulfide (PbS). Herein, the inorganic nanocrystals may be provided in form of spherical or elongate particles which may comprise a size from 2 nm to 20 nm, preferably from 2 nm to 10 nm, and which may from a blend with a selected donor polymer, such as a composite of CdSe nanocrystals and P3HT or of PbS nanoparticles and MEH-PPV. However, other kinds of blends may also be suitable.

Alternatively or in addition, the electron acceptor material may, preferably, comprise an acceptor polymer. As used herein, the term “acceptor polymer” refers to a polymer which may particularly be adapted to accept electrons as the electron acceptor material. Generally, conjugated polymers based on cyanated poly(phenylenevinylene), benzothiadiazole, perylene or naphtha-lenediimide are preferred for this purpose. In particular, the acceptor polymer may, preferably, be selected from one or more of the following polymers:
a cyano-poly[phenylenevinylene] (CN-PPV), such as C6-CN-PPV or C8-CN-PPV,
poly[5-(2-(ethylhexyloxy)-2-methoxycyanoterephthalyliden] (MEH-CN-PPV),
poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV),
poly[1,4-dioctyloxyl-p-2,5-dicyanophenylenevinylene] (DOCN-PPV),
poly[9,9′-dioctylfluoreneco-benzothiadiazole] (PF8BT),

or a derivative, a modification, or a mixture thereof. However, other kinds of acceptor polymers may also be suitable.

For more details concerning the mentioned compounds which may be used as the donor polymer or the electron acceptor material, reference may be made to the above-mentioned review articles by L. Biana et al., A. Facchetti, and S. Günes et al., as well as the respective references cited therein. Further compounds are described in the dissertation of F. A. Sperlich, Electron Paramagnetic Resonance Spectroscopy of Conjugated Polymers and Fullerenes for Organic Photovoltaics, Julius-Maximilians-Universität Würzburg, 2013, and the references cited therein.

As further mentioned above, the photoactive layer is embedded between the at least two electrodes as comprised within the photodiode. As generally used, the term “electrode” refers to a highly electrically conducting material, wherein an electrical conductance may be in a metallic or a highly-conducting semiconducting range, which stays in contact with a poorly conducting or a non-conducting material. In particular for the purpose of facilitating the light beam which may impinge the photodiode to arrive at the photoactive layer, at least one of the electrodes, in particular the electrode which may be located within the path of the incident light beam, can, concurrently, at least partially be optically transparent. Herein, the at least partially optically transparent electrode may comprise at least one transparent conductive oxide (TCO), in particular at least one of indium-doped tin oxide (ITO), fluorine-doped tin oxide (FTO), and aluminum-doped zinc oxide (AZO). Alternatively, an insulator-metal-insulator structure may also be applicable here, such as a thin metal layer located between two TCO layers, in particular an Ag layer having a thickness a few nm only of located between two ITO layers. However, other kinds of optically transparent materials which may be suited as electrode material may also be applicable, such as PEDOT. Further, in particular when using a minimum of the optically transparent material but still in order to increase a mechanical stability of the at least partially optically transparent electrode, an optically transparent substrate, which may particularly be selected from a glass substrate, from a quartz substrate, or from a substrate comprising an optically transparent but electrically insulating polymer, such as polyethylene terephthalate (PET), can at least partially be covered with the at least partially optically transparent electrode. By these kinds of setup it may, thus, be possible to obtain a thin electrode layer on the transparent substrate which together may, nevertheless, exhibit sufficient mechanical stability.

Besides the at least one optically transparent electrode, the remaining one or more electrodes, in particularly the one or more electrodes which are located outside the path of the light beam impinging on the photodiode, may be optically intransparent and, preferably, reflective in order to increase the illumination within the photoactive layer. In this particular embodiment, the at least one optically intransparent electrode may, preferably, comprise a metal electrode, in particular one or more of a silver (Ag) electrode, a platinum (Pt) electrode, a gold (Au) electrode, and an aluminum (Al) electrode. Again, in particular when using a minimum of the optically intransparent material but still in order to increase the mechanical stability of the optically intransparent electrode, the metal electrode may comprise a thin layer of the metal, such as a thin metal film, a layer of graphene, or a layer of nanotubes, being deposited onto a substrate. Herein, the substrate may also optically be intransparent, however, an at least partially optically transparent substrate might also be applicable.

In a particularly preferred embodiment of the photodiode as employed within the optical sensor according to the present invention, the photoactive layer may be embedded between two different kinds of charge-influencing layers, wherein the two different kinds of charge-influencing layers comprise, for the same kind of charge carriers, a charge-carrier blocking layer and a charge-carrier transporting layer or, for two different kinds of charge carriers, two different charge-carrier blocking layers or two different charge-carrier transporting layers. As generally used, the term “charge carrier” related to either electrons or holes which are adapted to provide, block and/or transport electrical charges within a solid-state material. Consequently, the term “charge-influencing layer” or, alternatively the term “charge-manipulating layer”, refers to a material being adapted to influence a transport of one kind of charge carriers. In particular, the term “charge-carrier transporting layer” refers to a material being adapted to transport charge carriers, i.e. electrons or holes, on a way through the material whereas the term “charge-carrier blocking layer” relates to a material which is adapted to inhibit the transport of the corresponding charges through the respective layer. Thus, the photoactive layer may be embedded between a charge-carrier blocking layer and a charge-carrier transporting layer. Alternatively, two different kinds of charge-carrier blocking layers may be present in order to embed the photoactive layer. Herein, a first charge-carrier blocking layer may be a hole blocking layer while a second charge-carrier blocking layer may be an electron blocking layer. As mentioned above, the hole blocking layer may, thus, be adapted to inhibit the transport of holes through the layer while the electron blocking layer may be adapted to inhibit the transport of electrons through the layer. However, both kinds of arrangements may, in general, be equivalent since a layer adapted to inhibit the transport of a specific charge carrier may be capable of achieving a similar effect as a layer that may be adapted to facilitate the transport of the oppositely charged charge carrier. By way of example, instead of using a hole transporting layer an electron blocking layer may, alternatively, be employed here in order to accomplish the embedding of the photoactive layer in accordance with the present invention. Consequently, the photoactive layer may, thus, preferably be furnished with two selective contacts, wherein a first selective contact may be adapted to block electrons and transport only holes while a second selective contact may be adapted to block holes and transport only electrons.

Similarly as mentioned above, for the purpose of facilitating the light beam which may impinge the photodiode to arrive at the photoactive layer, at least one of the charge-carrier blocking layer and the charge-carrier transporting layer, in particular the layer which might be located within the path of the incident light beam and, thus, be located adjacent to the at least partially optically transparent electrode, may, concurrently, at least partially be optically transparent. In order to maintain characteristics of the photodiode, the thickness of the charge-carrier blocking layer may be in a range in order to allow achieving a significant short-circuit current through the charge-carrier blocking layer under illumination of the photodiode, in particular in the range from 1 nm to 100 nm.

In a particularly preferred embodiment, the charge-carrier blocking layer may be a hole blocking layer. Herein, the hole blocking layer may, preferably, comprise at least one of:
a carbonate, in particular cesium carbonate (Cs₂CO₃),
polyethylenimine (PEI),
polyethylenimine ethoxylated (PEIE),
2,9-dimethyl-4,7-diphenylphenanthroline (BCP),
(3-(4-biphenylyl)-4-phenyl-5-(4-tert-butylphenyl)-1,2,4-triazole) (TAZ),
a transition metal oxide, in particular zinc oxide (ZnO) or titanium dioxide (TiO₂), or
an alkaline fluoride, in particular lithium fluoride (LiF) or sodium fluoride (NaF).

In this particularly preferred embodiment, the charge-carrier transporting layer may, accordingly, be a hole transporting layer being designated to selectively transport holes. Herein, the hole transporting layer may, preferably, be selected from the group consisting of:
a poly-3,4-ethylenedioxythiophene (PEDOT), preferably PEDOT electrically doped with at least one counter ion, more preferably PEDOT doped with sodium polystyrene sulfonate (PEDOT:PSS);
a polyaniline (PANI);
a sulfonated tetrafluoroethylene-based fluoropolymer-copolymer (Nafion); and
a polythiophene(PT).

As mentioned above, instead of using a hole transporting layer an electron blocking layer may, alternatively, be employed here, wherein the electron blocking layer may be designated to block electrons from being transported, such as by alignment of the work functions or by forming of a dipole layer. In particular, the electron blocking layer may, preferably, be selected from the group consisting of:
a molybdenum oxide, usually denoted by MoO₃; and
a nickel oxide, such as NiO, Ni₂O₃, a modification, or a mixture thereof.

However, other kinds of materials and combinations of these materials among themselves and/or with the mentioned materials may also be applicable. Further, the photodiode may, alternatively, comprise an electron blocking layer and an electron transporting layer. Further, the photodiode may, additionally, comprise one or more further layers which may be adapted for one or more specific purposes.

For the purpose of facilitating a production of the photodiode suitable for the optical sensor according to the present invention, at least one, preferably all, of the photoactive layers, the charge-carrier blocking layer and the charge-carrier transporting layer may be provided by using a deposition method, preferably by a coating method, more preferred by a spin-coating method, a slot-coating method, a blade-coating method, or, alternatively, by evaporation. Thus, the resulting layer may, preferably, be a spin-cast layer, a slot-coated layer, or a blade-coated layer. Further, as mentioned above, one or more of the electrodes within the photodiode may be provided as thin layers on a corresponding substrate. For this purpose, the respective electrode material may also be deposited onto the corresponding substrate by using a suitable deposition method, such as a coating or evaporation method.

The production of the photodiode suitable for the optical sensor according to the present invention, in particular by using the described deposition methods, implicate considerable advantages with respect to employing a dye-sensitized solar cell (DSC), preferably a solid-state dye-sensitized solar cell (ssDSC), within the sensor region of the FiP sensor. An application of deposition methods does not require one or more annealing steps of the materials involved. By using appropriate organic polymers the temperature used within this kind of production methods may be selected to accomplish a temperature below 140° C., below 120° C., below 100° C., or even less, particularly depending on the choice of the organic polymer within the photoactive layer. Moreover, the application of the deposition methods allows a faster production of the photodiodes according to the present invention since, generally, the deposition methods as employed here require less time compared to time-consuming annealing processes.

As used herein, the term “evaluation device” generally refers to an arbitrary device designed to generate the items of information, i.e. the at least one item of information on the position of the object. As an example, the evaluation device may be or may comprise one or more integrated circuits, such as one or more application-specific integrated circuits (ASICs), and/or one or more data processing devices, such as one or more computers, preferably one or more microcomputers and/or microcontrollers. Additional components may be comprised, such as one or more preprocessing devices and/or data acquisition devices, such as one or more devices for receiving and/or preprocessing of the sensor signals, such as one or more AD-converters and/or one or more filters. As used herein, the sensor signal may generally refer to one of the longitudinal sensor signal and, if applicable, to the transversal sensor signal. Further, the evaluation device may comprise one or more data storage devices. Further, as outlined above, the evaluation device may comprise one or more interfaces, such as one or more wireless interfaces and/or one or more wire-bound interfaces.

The at least one evaluation device may be adapted to perform at least one computer program, such as at least one computer program performing or supporting the step of generating the items of information. As an example, one or more algorithms may be implemented which, by using the sensor signals as input variables, may perform a predetermined transformation into the position of the object.

The evaluation device may particularly comprise at least one data processing device, in particular an electronic data processing device, which can be designed to generate the items of information by evaluating the sensor signals. Thus, the evaluation device is designed to use the sensor signals as input variables and to generate the items of information on the transversal position and the longitudinal position of the object by processing these input variables. The processing can be done in parallel, subsequently or even in a combined manner. The evaluation device may use an arbitrary process for generating these items of information, such as by calculation and/or using at least one stored and/or known relationship. Besides the sensor signals, one or a plurality of further parameters and/or items of information can influence said relationship, for example at least one item of information about a modulation frequency. The relationship can be determined or be determinable empirically, analytically or else semi-empirically. Particularly preferably, the relationship comprises at least one calibration curve, at least one set of calibration curves, at least one function or a combination of the possibilities mentioned. One or a plurality of calibration curves can be stored for example in the form of a set of values and the associated function values thereof, for example in a data storage device and/or a table. Alternatively or additionally, however, the at least one calibration curve can also be stored for example in parameterized form and/or as a functional equation. Separate relationships for processing the sensor signals into the items of information may be used. Alternatively, at least one combined relationship for processing the sensor signals is feasible. Various possibilities are conceivable and can also be combined.

By way of example, the evaluation device can be designed in terms of programming for the purpose of determining the items of information. The evaluation device can comprise in particular at least one computer, for example at least one microcomputer. Furthermore, the evaluation device can comprise one or a plurality of volatile or nonvolatile data memories. As an alternative or in addition to a data processing device, in particular at least one computer, the evaluation device can comprise one or a plurality of further electronic components which are designed for determining the items of information, for example an electronic table and in particular at least one look-up table and/or at least one application-specific integrated circuit (ASIC).

The detector has, as described above, at least one evaluation device. In particular, the at least one evaluation device can also be designed to completely or partly control or drive the detector, for example by the evaluation device being designed to control at least one illumination source and/or to control at least one modulation device of the detector as described below in more detail. The evaluation device can be designed, in particular, to carry out at least one measurement cycle in which one or a plurality of sensor signals, such as a plurality of sensor signals, are picked up, for example a plurality of sensor signals of successively at different modulation frequencies of the illumination.

The evaluation device is designed, as described above, to generate at least one item of information on the position of the object by evaluating the at least one sensor signal. The position of the object can be static or may even comprise at least one movement of the object, for example a relative movement between the detector or parts thereof and the object or parts thereof. In this case, a relative movement can generally comprise at least one linear movement and/or at least one rotational movement. Items of movement information can for example also be obtained by comparison of at least two items of information picked up at different times, such that for example at least one item of location information can also comprise at least one item of velocity information and/or at least one item of acceleration information, for example at least one item of information about at least one relative velocity between the object or parts thereof and the detector or parts thereof. In particular, the at least one item of location information can generally be selected from: an item of information about a distance between the object or parts thereof and the detector or parts thereof, in particular an optical path length; an item of information about a distance or an optical distance between the object or parts thereof and the optional transfer device or parts thereof; an item of information about a positioning of the object or parts thereof relative to the detector or parts thereof; an item of information about an orientation of the object and/or parts thereof relative to the detector or parts thereof; an item of information about a relative movement between the object or parts thereof and the detector or parts thereof; an item of information about a two-dimensional or three-dimensional spatial configuration of the object or of parts thereof, in particular a geometry or form of the object. Generally, the at least one item of location information can therefore be selected for example from the group consisting of: an item of information about at least one location of the object or at least one part thereof; information about at least one orientation of the object or a part thereof; an item of information about a geometry or form of the object or of a part thereof, an item of information about a velocity of the object or of a part thereof, an item of information about an acceleration of the object or of a part thereof, an item of information about a presence or absence of the object or of a part thereof in a visual range of the detector.

The at least one item of location information can be specified for example in at least one coordinate system, for example a coordinate system in which the detector or parts thereof rest. Alternatively or additionally, the location information can also simply comprise for example a distance between the detector or parts thereof and the object or parts thereof. Combinations of the possibilities mentioned are also conceivable.

As described above, the detector according to the present invention, preferably, comprises a single individual longitudinal optical sensor. However, in a particular embodiment, such as when the different longitudinal optical sensors may exhibit different spectral sensitivities with respect to the incident light beam, the detector may comprise at least two longitudinal optical sensors, wherein each longitudinal optical sensor may be adapted to generate at least one longitudinal sensor signal. As an example, the sensor areas or the sensor surfaces of the longitudinal optical sensors may, thus, be oriented in parallel, wherein slight angular tolerances might be tolerable, such as angular tolerances of no more than 10°, preferably of no more than 5°. Herein, preferably all of the longitudinal optical sensors of the detector, which may, preferably, be arranged in form of a stack along the optical axis of the detector, may be transparent. Thus, the light beam may pass through a first transparent longitudinal optical sensor before impinging on the other longitudinal optical sensors, preferably subsequently. Thus, the light beam from the object may subsequently reach all longitudinal optical sensors present in the optical detector.

Within this regard, the detector according to the present invention may comprise a stack of optical sensors as disclosed in WO 2014/097181 A1, in particular in a combination of one or more longitudinal optical sensors with one or more transversal optical sensors. As an example, one or more transversal optical sensors may be located on a side of the at least one longitudinal optical sensor facing towards the object. Alternatively or additionally, one or more transversal optical sensors may be located on a side of the at least one longitudinal optical sensor facing away from the object. Again, additionally or alternatively, one or more transversal optical sensors may be interposed in between at least two longitudinal optical sensors arranged within the stack. Further, the stack of optical sensors may be a combination of a single individual longitudinal optical sensor with a single individual transversal optical sensor. However, an embodiment which may only comprise a single individual longitudinal optical sensor and no transversal optical sensor may still be advantageous, such as in a case in which determining solely the depth of the object may be desired.

As used herein, the term “transversal optical sensor” generally refers to a device which is adapted to determine a transversal position of at least one light beam traveling from the object to the detector. With regard to the term position, reference may be made to the definition above. Thus, preferably, the transversal position may be or may comprise at least one coordinate in at least one dimension perpendicular to an optical axis of the detector. As an example, the transversal position may be a position of a light spot generated by the light beam in a plane perpendicular to the optical axis, such as on a light-sensitive sensor surface of the transversal optical sensor. As an example, the position in the plane may be given in Cartesian coordinates and/or polar coordinates. Other embodiments are feasible. For potential embodiments of the transversal optical sensor, reference may be made to WO 2014/097181 A1 or WO 2016/120392A1. However, other embodiments are feasible and will be outlined in further detail below.

The transversal optical sensor may provide at least one transversal sensor signal. Herein, the transversal sensor signal may generally be an arbitrary signal indicative of the transversal position. As an example, the transversal sensor signal may be or may comprise a digital and/or an analog signal. As an example, the transversal sensor signal may be or may comprise a voltage signal and/or a current signal. Additionally or alternatively, the transversal sensor signal may be or may comprise digital data. The transversal sensor signal may comprise a single signal value and/or a series of signal values. The transversal sensor signal may further comprise an arbitrary signal which may be derived by combining two or more individual signals, such as by averaging two or more signals and/or by forming a quotient of two or more signals.

The transversal optical sensor may be a photo detector according to WO 2012/110924 A1 and/or WO 2014/097181 A1, having at least one first electrode, at least one second electrode and at least one photovoltaic material, wherein the photovoltaic material may be embedded in between the first electrode and the second electrode. Thus, the transversal optical sensor may be or may comprise one or more photo detectors, such as one or more organic photodetectors and, most preferably, one or more dye-sensitized organic solar cells (DSCs, also referred to as dye solar cells), such as one or more solid dye-sensitized organic solar cells (s-DSCs). Thus, the detector may comprise one or more DSCs (such as one or more sDSCs) acting as the at least one transversal optical sensor and one or more DSCs (such as one or more sDSCs) acting as the at least one longitudinal optical sensor.

Further, the transversal optical sensor according to the present invention may, as disclosed in the European patent application 15 153 215.7, filed Jan. 30, 2015, the full content of which is incorporated herein by reference, comprise at least one first electrode, at least one second electrode and a layer of a photoconductive material, particularly, embedded in between the first electrode and the second electrode. Thus, the transversal optical sensor may comprise one of the photoconductive materials mentioned elsewhere herein, in particular a chalcogenide, preferably, lead sulfide or lead selenide. Again, the layer of the photoconductive material may comprise a composition selected from a homogeneous, a crystalline, a polycrystalline, a nanocrystalline and/or an amorphous phase. Preferably, the layer of the photoconductive material may be embedded in between two layers of a transparent conducting oxide, preferably comprising indium tin oxide (ITO) or an optically transparent material as described above, which may serve as the first electrode and the second electrode. However, other materials may be feasible, in particular according to the desired transparency range within the optical spectrum.

Further, at least two electrodes may be present for recording the transversal optical signal. Preferably, the at least two electrodes may actually be arranged in the form of at least two physical electrodes, wherein each physical electrode may comprise an electrically conducting material, preferably a metallically conducting material, more preferred a highly metallically conducting material such as copper, silver, gold or an alloy or a composition comprising these kinds of materials. Herein, each of the at least two physical electrodes may, preferably, be arranged in a manner that a direct electrical contact between the respective electrode and the photoconductive layer in the optical sensor may be achieved, particularly in order to acquire the longitudinal sensor signal with as little loss as possible, such as due to additional resistances in a transport path between the optical sensor and the evaluation device.

Preferably, at least one of the electrodes of the transversal optical sensor may be a split electrode having at least two partial electrodes, wherein the transversal optical sensor may have a sensor area, wherein the at least one transversal sensor signal may indicate an x- and/or a y-position of the incident light beam within the sensor area. The sensor area may be a surface of the photo detector facing towards the object. The sensor area preferably may be oriented perpendicular to the optical axis. Thus, the transversal sensor signal may indicate a position of a light spot generated by the light beam in a plane of the sensor area of the transversal optical sensor. Generally, as used herein, the term “partial electrode” refers to an electrode out of a plurality of electrodes, adapted for measuring at least one current and/or voltage signal, preferably independent from other partial electrodes. Thus, in case a plurality of partial electrodes is provided, the respective electrode is adapted to provide a plurality of electric potentials and/or electric currents and/or voltages via the at least two partial electrodes, which may be measured and/or used independently.

The transversal optical sensor may further be adapted to generate the transversal sensor signal in accordance with the electrical currents through the partial electrodes. Thus, a ratio of electric currents through two horizontal partial electrodes may be acquired, thereby generating an x-coordinate, and/or a ratio of electric currents through to vertical partial electrodes may be generated, thereby generating a y-coordinate. The detector, preferably the transversal optical sensor and/or the evaluation device, may be adapted to derive the information on the transversal position of the object from at least one ratio of the currents through the partial electrodes. Other ways of generating position coordinates by comparing currents through the partial electrodes are feasible.

The partial electrodes may generally be defined in various ways, in order to determine a position of the light beam in the sensor area. Thus, two or more horizontal partial electrodes may be provided in order to determine a horizontal coordinate or x-coordinate, and two or more vertical partial electrodes may be provided in order to determine a vertical coordinate or y-coordinate. Thus, the partial electrodes may be provided at a rim of the sensor area, wherein an interior space of the sensor area remains free and may be covered by one or more additional electrode materials. As will be outlined in further detail below, the additional electrode material preferably may be a transparent additional electrode material, such as a transparent metal and/or a transparent conductive oxide and/or, most preferably, a transparent conductive polymer.

By using the transversal optical sensor, wherein one of the electrodes may be a split electrode with three or more partial electrodes, currents through the partial electrodes may be dependent on a position of the light beam in the sensor area. This may generally be due to the fact that Ohmic losses or resistive losses may occur on the way from a location of generation of electrical charges due to the impinging light onto the partial electrodes. Thus, besides the partial electrodes, the split electrode may comprise one or more additional electrode materials connected to the partial electrodes, wherein the one or more additional electrode materials provide an electrical resistance. Thus, due to the Ohmic losses on the way from the location of generation of the electric charges to the partial electrodes through with the one or more additional electrode materials, the currents through the partial electrodes depend on the location of the generation of the electric charges and, thus, to the position of the light beam in the sensor area. For details of this principle of determining the position of the light beam in the sensor area, reference may be made to the preferred embodiments below and/or to the physical principles and device options as disclosed in WO 2014/097181 A1 and the respective references therein.

Accordingly, the transversal optical sensor may comprise the sensor area, which, preferably, may be transparent to the light beam travelling from the object to the detector. The transversal optical sensor may, therefore, be adapted to determine a transversal position of the light beam in one or more transversal directions, such as in the x- and/or in the y-direction. For this purpose, the at least one transversal optical sensor may further be adapted to generate at least one transversal sensor signal. Thus, the evaluation device may be designed to generate at least one item of information on a transversal position of the object by evaluating the transversal sensor signal of the longitudinal optical sensor.

Further embodiments of the present invention referred to the nature of the light beam which propagates from the object to the detector. As used herein, the term “light” generally refers to electromagnetic radiation in one or more of the visible spectral range, the ultraviolet spectral range and the infrared spectral range. Therein, the term visible spectral range generally refers to a spectral range of 380 nm to 780 nm. The term infrared (IR) spectral range generally refers to electromagnetic radiation in the range of 780 nm to 1000 μm, wherein the range of 780 nm to 1.4 μm is usually denominated as the near infrared (NIR) spectral range, and the range from 15 μm to 1000 μm as the far infrared (FIR) spectral range. The term ultraviolet spectral range generally refers to electromagnetic radiation in the range of 1 nm to 380 nm, preferably in the range of 100 nm to 380 nm. Preferably, light as used within the present invention is visible light, i.e. light in the visible spectral range.

The term “light beam” generally refers to an amount of light emitted into a specific direction. Thus, the light beam may be a bundle of the light rays having a predetermined extension in a direction perpendicular to a direction of propagation of the light beam. Preferably, the light beam may be or may comprise one or more Gaussian light beams which may be characterized by one or more Gaussian beam parameters, such as one or more of a beam waist, a Rayleigh-length or any other beam parameter or combination of beam parameters suited to characterize a development of a beam diameter and/or a beam propagation in space.

The light beam might be emitted by the object itself, i.e. might originate from the object. Additionally or alternatively, another origin of the light beam is feasible. Thus, as will be outlined in further detail below, one or more illumination sources might be provided which illuminate the object, such as by using one or more primary rays or beams, such as one or more primary rays or beams having a predetermined characteristic. In the latter case, the light beam propagating from the object to the detector might be a light beam which is reflected by the object and/or a reflection device connected to the object.

As outlined above, the at least one longitudinal sensor signal, given the same total power of the illumination by the light beam, is, according to the FiP effect, dependent on a beam cross-section of the light beam in the sensor region of the at least one longitudinal optical sensor. As used herein, the term beam cross-section generally refers to a lateral extension of the light beam or a light spot generated by the light beam at a specific location. In case a circular light spot is generated, a radius, a diameter or a Gaussian beam waist or twice the Gaussian beam waist may function as a measure of the beam cross-section. In case non-circular light-spots are generated, the cross-section may be determined in any other feasible way, such as by determining the cross-section of a circle having the same area as the non-circular light spot, which is also referred to as the equivalent beam cross-section. Within this regard, it may be possible to employ the observation of an extremum, i.e. a maximum or a minimum, of the longitudinal sensor signal, in particular a global extremum, under a condition in which the corresponding material, such as a photovoltaic material, may be impinged by a light beam with the smallest possible cross-section, such as when the material may be located at or near a focal point as affected by an optical lens. In case the extremum is a maximum, this observation may be denominated as the positive FiP-effect, while in case the extremum is a minimum, this observation may be denominated as the negative FiP-effect. As demonstrated in the embodiments below, the optical sensor comprising the photodiode having the photoactive layer within the sensor region according to the present invention, may exhibit the FiP effect, in particular depending on the material selected for the photoactive layer and/or the power of the illumination, one of the positive FiP effect or, alternatively, the negative FiP effect.

Thus, irrespective of the material actually comprised in the sensor region but given the same total power of the illumination of the sensor region by the light beam, a light beam having a first beam diameter or beam cross-section may generate a first longitudinal sensor signal, whereas a light beam having a second beam diameter or beam-cross section being different from the first beam diameter or beam cross-section generates a second longitudinal sensor signal being different from the first longitudinal sensor signal. As described in WO 2012/110924 A1, by comparing the longitudinal sensor signals, at least one item of information on the beam cross-section, specifically on the beam diameter, may be generated. Accordingly, the longitudinal sensor signals generated by the longitudinal optical sensors may be compared, in order to gain information on the total power and/or intensity of the light beam and/or in order to normalize the longitudinal sensor signals and/or the at least one item of information on the longitudinal position of the object for the total power and/or total intensity of the light beam. Thus, as an example, a maximum value of the longitudinal optical sensor signals may be detected, and all longitudinal sensor signals may be divided by this maximum value, thereby generating normalized longitudinal optical sensor signals, which, then, may be transformed by using the above-mentioned known relationship, into the at least one item of longitudinal information on the object. Other ways of normalization are feasible, such as a normalization using a mean value of the longitudinal sensor signals and dividing all longitudinal sensor signals by the mean value. Other options are possible.

This embodiment may, particularly, be used by the evaluation device in order to resolve an ambiguity in the known relationship between a beam cross-section of the light beam and the longitudinal position of the object. Thus, even if the beam properties of the light beam propagating from the object to the detector are known fully or partially, it is known that, in many beams, the beam cross-section narrows before reaching a focal point and, afterwards, widens again. Thus, before and after the focal point in which the light beam has the narrowest beam cross-section, positions along the axis of propagation of the light beam occur in which the light beam has the same cross-section. Thus, as an example, at a distance z0 before and after the focal point, the cross-section of the light beam is identical. Thus, in case the optical detector only comprises a single longitudinal optical sensor, a specific cross-section of the light beam might be determined, in case the overall power or intensity of the light beam is known. By using this information, the distance z0 of the respective longitudinal optical sensor from the focal point might be determined. However, in order to determine whether the respective longitudinal optical sensor may be located before or behind the focal point, additional information is required, such as a history of movement of the object and/or the detector and/or information on whether the detector is located before or behind the focal point.

In case one or more beam properties of the light beam propagating from the object to the detector are known, the at least one item of information on the longitudinal position of the object may thus be derived from a known relationship between the at least one longitudinal sensor signal and a longitudinal position of the object. The known relationship may be stored in the evaluation device as an algorithm and/or as one or more calibration curves. As an example, specifically for Gaussian beams, a relationship between a beam diameter or beam waist and a position of the object may easily be derived by using the Gaussian relationship between the beam waist and a longitudinal coordinate. Thus, as described in WO 2014/097181 A1 and also according to the present invention, the evaluation device may be adapted to compare the beam cross-section and/or the diameter of the light beam with known beam properties of the light beam in order to determine the at least one item of information on the longitudinal position of the object, preferably from a known dependency of a beam diameter of the light beam on at least one propagation coordinate in a direction of propagation of the light beam and/or from a known Gaussian profile of the light beam.

In addition to the at least one longitudinal coordinate of the object, at least one transversal coordinate of the object may be determined. Thus, generally, the evaluation device may further be adapted to determine at least one transversal coordinate of the object by determining a position of the light beam on the at least one transversal optical sensor, which may be a pixelated, a segmented or a large-area transversal optical sensor, as further outlined also in WO 2014/097181 A1.

In addition, the detector may comprise at least one transfer device, such as an optical lens, in particular one or more refractive lenses, particularly converging thin refractive lenses, such as convex or biconvex thin lenses, and/or one or more convex mirrors, which may further be arranged along the common optical axis. Most preferably, the light beam which emerges from the object may in this case travel first through the at least one transfer device and thereafter through the single transparent longitudinal optical sensor or the stack of the transparent longitudinal optical sensors until it may finally impinge on an imaging device. As used herein, the term “transfer device” refers to an optical element which may be configured to transfer the at least one light beam emerging from the object to optical sensors within the detector, i.e. the at least two longitudinal optical sensors and the at least one optional transversal optical sensor. Thus, the transfer device can be designed to feed light propagating from the object to the detector to the optical sensors, wherein this feeding can optionally be effected by means of imaging or else by means of non-imaging properties of the transfer device. In particular the transfer device can also be designed to collect the electromagnetic radiation before the latter is fed to the transversal and/or longitudinal optical sensor.

In addition, the at least one transfer device may have imaging properties. Consequently, the transfer device comprises at least one imaging element, for example at least one lens and/or at least one curved mirror, since, in the case of such imaging elements, for example, a geometry of the illumination on the sensor region can be dependent on a relative positioning, for example a distance, between the transfer device and the object. As used herein, the transfer device may be designed in such a way that the electromagnetic radiation which emerges from the object is transferred completely to the sensor region, for example is focused completely onto the sensor region, in particular the sensor area, in particular if the object is arranged in a visual range of the detector.

In addition, the transfer device may also be employed for modulating light beams, such as by using a modulating transfer device. Herein, the modulating transfer device may be adapted to modulate the frequency and/or the intensity of an incident light beam before the light beam might impinge on the longitudinal optical sensor. Herein, the modulating transfer device may comprise means for modulating light beams and/or may be controlled by the modulation device, which may be a constituent part of the evaluation device and/or may be at least partially implemented as a separate unit.

Accordingly, the detector according to the present invention may comprise at least one modulation device which may be capable of generating at least one modulated light beam traveling from the object to the detector and, thus, modulates the illumination of the object and/or at least one sensor region of the detector, such as at least one sensor region of the at least one longitudinal optical sensor. Preferably, the modulation device may be employed for generating a periodic modulation, such as by employing a periodic beam interrupting device. By way of example, the detector can be designed to bring about a modulation of the illumination of the object and/or at least one sensor region of the detector, such as at least one sensor region of the at least one longitudinal optical sensor, with a frequency of 0.05 Hz to 1 MHz, such as 0.1 Hz to 10 kHz. Within this regard, the modulation of the illumination is understood to mean a process in which a total power of the illumination is varied, preferably periodically, in particular with a single modulation frequency or, simultaneously and/or consecutively, with a plurality of modulation frequencies. In particular, a periodic modulation can be effected between a maximum value and a minimum value of the total power of the illumination. Herein, the minimum value can be 0, but can also exceed 0, such that, by way of example, complete modulation does not have to be effected. In a particularly preferential manner, the at least one modulation may be or may comprise a periodic modulation, such as a sinusoidal modulation, a square modulation, or a triangular modulation of the affected light beam. Further, the modulation may be a linear combination of two or more sinusoidal functions, such as a squared sinusoidal function, or a sin(t²) function, where t denotes time. In order to demonstrate particular effects, advantages and feasibility of the present invention the square modulation is, in general, employed herein as an exemplary shape of the modulation which representation is, however, not intended to limit the scope of the present invention to this specific shape of the modulation. By virtue of this example, the skilled person may rather easily recognize how to adapt the related parameters and conditions when employing a different shape of the modulation.

The modulation can be effected for example in a beam path between the object and the optical sensor, for example by the at least one modulation device being arranged in said beam path. Alternatively or additionally, however, the modulation can also be effected in a beam path between an optional illumination source as described below for illuminating the object and the object, for example by the at least one modulation device being arranged within said beam path. A combination of these possibilities may also be conceivable. For this purpose, the at least one modulation device can comprise, for example, a beam chopper or some other type of periodic beam interrupting device, such as comprising at least one interrupter blade or interrupter wheel, which preferably rotates at constant speed and which can, thus, periodically interrupt the illumination. Alternatively or additionally, however, it is also possible to use one or a plurality of different types of modulation devices, for example modulation devices based on an electro-optical effect and/or an acousto-optical effect. Once again alternatively or additionally, the at least one optional illumination source itself can also be designed to generate a modulated illumination, for example by the illumination source itself having a modulated intensity and/or total power, for example a periodically modulated total power, and/or by said illumination source being embodied as a pulsed illumination source, for example as a pulsed laser. Thus, by way of example, the at least one modulation device can also be wholly or partly integrated into the illumination source. Further, alternatively or in addition, the detector may comprise at least one optional transfer device, such as a tunable lens, which may itself be designed to modulate the illumination, for example by modulating, in particular by periodically modulating, the total intensity and/or total power of an incident light beam which impinges the at least one transfer device in order to traverse it before impinging the at least one longitudinal optical sensor. Various possibilities are feasible.

Further, given the same total power of the illumination, the longitudinal sensor signal may, thus, be dependent on the modulation frequency of the modulation of the illumination. For potential embodiments of the longitudinal optical sensor and the longitudinal sensor signal, including its dependency on the beam cross-section of the light beam within the sensor region and on the modulation frequency, reference may be made to the optical sensor as disclosed in WO 2012/110924 A1 and 2014/097181 A1. Within this respect, the detector can be designed in particular to detect at least two longitudinal sensor signals in the case of different modulations, in particular at least two longitudinal sensor signals at respectively different modulation frequencies. The evaluation device can be designed to generate the geometrical information from the at least two longitudinal sensor signals. As described in WO 2012/110924 A1 and WO 2014/097181 A1, it may be possible to resolve ambiguities and/or it is possible to take account of the fact that, for example, a total power of the illumination is generally unknown.

Generally, the detector may further comprise at least one imaging device, i.e. a device capable of acquiring at least one image. The imaging device can be embodied in various ways. Thus, the imaging device can be for example part of the detector in a detector housing. Alternatively or additionally, however, the imaging device can also be arranged outside the detector housing, for example as a separate imaging device. Alternatively or additionally, the imaging device can also be connected to the detector or even be part of the detector. In a preferred arrangement, the stack of the transparent longitudinal optical sensors and the imaging device are aligned along a common optical axis along which the light beam travels. Thus, it may be possible to locate an imaging device in the optical path of the light beam in a manner that the light beam travels through the stack of the transparent longitudinal optical sensors until it impinges on the imaging device. However, other arrangements are possible.

As used herein, an “imaging device” is generally understood as a device which can generate a one-dimensional, a two-dimensional, or a three-dimensional image of the object or of a part thereof. In particular, the detector, with or without the at least one optional imaging device, can be completely or partly used as a camera, such as an IR camera, or an RGB camera, i.e. a camera which is designed to deliver three basic colors which are designated as red, green, and blue, on three separate connections. Thus, as an example, the at least one imaging device may be or may comprise at least one imaging device selected from the group consisting of: a pixelated organic camera element, preferably a pixelated organic camera chip; a pixelated inorganic camera element, preferably a pixelated inorganic camera chip, more preferably a CCD-chip or CMOS-chip; a monochrome camera element, preferably a monochrome camera chip; a multicolor camera element, preferably a multicolor camera chip; a full-color camera element, preferably a full-color camera chip. The imaging device may be or may comprise at least one device selected from the group consisting of a monochrome imaging device, a multi-chrome imaging device and at least one full color imaging device. A multi-chrome imaging device and/or a full color imaging device may be generated by using filter techniques and/or by using intrinsic color sensitivity or other techniques, as the skilled person will recognize. Other embodiments of the imaging device are also possible.

The imaging device may be designed to image a plurality of partial regions of the object successively and/or simultaneously. By way of example, a partial region of the object can be a one-dimensional, a two-dimensional, or a three-dimensional region of the object which is delimited for example by a resolution limit of the imaging device and from which electromagnetic radiation emerges. In this context, imaging should be understood to mean that the electromagnetic radiation which emerges from the respective partial region of the object is fed into the imaging device, for example by means of the at least one optional transfer device of the detector. The electromagnetic rays can be generated by the object itself, for example in the form of a luminescent radiation. Alternatively or additionally, the at least one detector may comprise at least one illumination source for illuminating the object.

In particular, the imaging device can be designed to image sequentially, for example by means of a scanning method, in particular using at least one row scan and/or line scan, the plurality of partial regions sequentially. However, other embodiments are also possible, for example embodiments in which a plurality of partial regions is simultaneously imaged. The imaging device is designed to generate, during this imaging of the partial regions of the object, signals, preferably electronic signals, associated with the partial regions. The signal may be an analogue and/or a digital signal. By way of example, an electronic signal can be associated with each partial region. The electronic signals can accordingly be generated simultaneously or else in a temporally staggered manner. By way of example, during a row scan or line scan, it is possible to generate a sequence of electronic signals which correspond to the partial regions of the object, which are strung together in a line, for example. Further, the imaging device may comprise one or more signal processing devices, such as one or more filters and/or analogue-digital-converters for processing and/or preprocessing the electronic signals.

Light emerging from the object can originate in the object itself, but can also optionally have a different origin and propagate from this origin to the object and subsequently toward the optical sensors. The latter case can be affected for example by at least one illumination source being used. The illumination source can be embodied in various ways. Thus, the illumination source can be for example part of the detector in a detector housing. Alternatively or additionally, however, the at least one illumination source can also be arranged outside a detector housing, for example as a separate light source. The illumination source can be arranged separately from the object and illuminate the object from a distance. Alternatively or additionally, the illumination source can also be connected to the object or even be part of the object, such that, by way of example, the electromagnetic radiation emerging from the object can also be generated directly by the illumination source. By way of example, at least one illumination source can be arranged on and/or in the object and directly generate the electromagnetic radiation by means of which the sensor region is illuminated. This illumination source can for example be or comprise an ambient light source and/or may be or may comprise an artificial illumination source. By way of example, at least one infrared emitter and/or at least one emitter for visible light and/or at least one emitter for ultraviolet light can be arranged on the object. By way of example, at least one light emitting diode and/or at least one laser diode can be arranged on and/or in the object. The illumination source can comprise in particular one or a plurality of the following illumination sources: a laser, in particular a laser diode, although in principle, alternatively or additionally, other types of lasers can also be used; a light emitting diode; an incandescent lamp; a neon light; a flame source; an organic light source, in particular an organic light emitting diode; a structured light source. Alternatively or additionally, other illumination sources can also be used. It is particularly preferred if the illumination source is designed to generate one or more light beams having a Gaussian beam profile, as is at least approximately the case for example in many lasers. For further potential embodiments of the optional illumination source, reference may be made to one of WO 2012/110924 A1 and WO 2014/097181 A1. Still, other embodiments are feasible.

The at least one optional illumination source generally may emit light in at least one of: the ultraviolet spectral range, preferably in the range of 200 nm to 380 nm; the visible spectral range (380 nm to 780 nm); the infrared spectral range, preferably in the range of 780 nm to 3.0 micrometers. Most preferably, the at least one illumination source is adapted to emit light in the visible spectral range, preferably in the range of 500 nm to 780 nm, most preferably at 650 nm to 750 nm or at 690 nm to 700 nm. Herein, it is particularly preferred when the illumination source may exhibit a spectral range which may be related to the spectral sensitivities of the longitudinal sensors, particularly in a manner to ensure that the longitudinal sensor which may be illuminated by the respective illumination source may provide a sensor signal with a high intensity which may, thus, enable a high-resolution evaluation with a sufficient signal-to-noise-ratio.

In a further aspect of the present invention, an arrangement comprising at least two detectors according to any of the preceding embodiments is proposed. Herein, the at least two detectors preferably may have identical optical properties but might also be different with respect from each other. In addition, the arrangement may further comprise at least one illumination source. Herein, the at least one object might be illuminated by using at least one illumination source which generates primary light, wherein the at least one object elastically or inelastically reflects the primary light, thereby generating a plurality of light beams which propagate to one of the at least two detectors. The at least one illumination source may form or may not form a constituent part of each of the at least two detectors. By way of example, the at least one illumination source itself may be or may comprise an ambient light source and/or may be or may comprise an artificial illumination source. This embodiment is preferably suited for an application in which at least two detectors, preferentially two identical detectors, are employed for acquiring depth information, in particular, for the purpose to providing a measurement volume which extends the inherent measurement volume of a single detector.

In a further aspect of the present invention, a human-machine interface for exchanging at least one item of information between a user and a machine is proposed. The human-machine interface as proposed may make use of the fact that the above-mentioned detector in one or more of the embodiments mentioned above or as mentioned in further detail below may be used by one or more users for providing information and/or commands to a machine. Thus, preferably, the human-machine interface may be used for inputting control commands.

The human-machine interface comprises at least one detector according to the present invention, such as according to one or more of the embodiments disclosed above and/or according to one or more of the embodiments as disclosed in further detail below, wherein the human-machine interface is designed to generate at least one item of geometrical information of the user by means of the detector wherein the human-machine interface is designed to assign the geometrical information to at least one item of information, in particular to at least one control command.

In a further aspect of the present invention, an entertainment device for carrying out at least one entertainment function is disclosed. As used herein, an entertainment device is a device which may serve the purpose of leisure and/or entertainment of one or more users, in the following also referred to as one or more players. As an example, the entertainment device may serve the purpose of gaming, preferably computer gaming. Additionally or alternatively, the entertainment device may also be used for other purposes, such as for exercising, sports, physical therapy or motion tracking in general. Thus, the entertainment device may be implemented into a computer, a computer network or a computer system or may comprise a computer, a computer network or a computer system which runs one or more gaming software programs.

The entertainment device comprises at least one human-machine interface according to the present invention, such as according to one or more of the embodiments disclosed above and/or according to one or more of the embodiments disclosed below. The entertainment device is designed to enable at least one item of information to be input by a player by means of the human-machine interface. The at least one item of information may be transmitted to and/or may be used by a controller and/or a computer of the entertainment device.

In a further aspect of the present invention, a tracking system for tracking the position of at least one movable object is provided. As used herein, a tracking system is a device which is adapted to gather information on a series of past positions of the at least one object or at least one part of an object. Additionally, the tracking system may be adapted to provide information on at least one predicted future position of the at least one object or the at least one part of the object. The tracking system may have at least one track controller, which may fully or partially be embodied as an electronic device, preferably as at least one data processing device, more preferably as at least one computer or microcontroller. Again, the at least one track controller may comprise the at least one evaluation device and/or may be part of the at least one evaluation device and/or might fully or partially be identical to the at least one evaluation device.

The tracking system comprises at least one detector according to the present invention, such as at least one detector as disclosed in one or more of the embodiments listed above and/or as disclosed in one or more of the embodiments below. The tracking system further comprises at least one track controller. The tracking system may comprise one, two or more detectors, particularly two or more identical detectors, which allow for a reliable acquisition of depth information about the at least one object in an overlapping volume between the two or more detectors. The track controller is adapted to track a series of positions of the object, each position comprising at least one item of information on a position of the object at a specific point in time.

The tracking system may further comprise at least one beacon device connectable to the object. For a potential definition of the beacon device, reference may be made to WO 2014/097181 A1. The tracking system preferably is adapted such that the detector may generate an information on the position of the object of the at least one beacon device, in particular to generate the information on the position of the object which comprises a specific beacon device exhibiting a specific spectral sensitivity. Thus, more than one beacon exhibiting a different spectral sensitivity may be tracked by the detector of the present invention, preferably in a simultaneous manner. Herein, the beacon device may fully or partially be embodied as an active beacon device and/or as a passive beacon device. As an example, the beacon device may comprise at least one illumination source adapted to generate at least one light beam to be transmitted to the detector. Additionally or alternatively, the beacon device may comprise at least one reflector adapted to reflect light generated by an illumination source, thereby generating a reflected light beam to be transmitted to the detector.

In a further aspect of the present invention, a scanning system for determining at least one position of at least one object is provided. As used herein, the scanning system is a device which is adapted to emit at least one light beam being configured for an illumination of at least one dot located at at least one surface of the at least one object and for generating at least one item of information about the distance between the at least one dot and the scanning system. For the purpose of generating the at least one item of information about the distance between the at least one dot and the scanning system, the scanning system comprises at least one of the detectors according to the present invention, such as at least one of the detectors as disclosed in one or more of the embodiments listed above and/or as disclosed in one or more of the embodiments below.

Thus, the scanning system comprises at least one illumination source which is adapted to emit the at least one light beam being configured for the illumination of the at least one dot located at the at least one surface of the at least one object. As used herein, the term “dot” refers to a small area on a part of the surface of the object which may be selected, for example by a user of the scanning system, to be illuminated by the illumination source. Preferably, the dot may exhibit a size which may, on one hand, be as small as possible in order to allow the scanning system determining a value for the distance between the illumination source comprised by the scanning system and the part of the surface of the object on which the dot may be located as exactly as possible and which, on the other hand, may be as large as possible in order to allow the user of the scanning system or the scanning system itself, in particular by an automatic procedure, to detect a presence of the dot on the related part of the surface of the object.

For this purpose, the illumination source may comprise an artificial illumination source, in particular at least one laser source and/or at least one incandescent lamp and/or at least one semiconductor light source, for example, at least one light-emitting diode, in particular an organic and/or inorganic light-emitting diode. On account of their generally defined beam profiles and other properties of handleability, the use of at least one laser source as the illumination source is particularly preferred. Herein, the use of a single laser source may be preferred, in particular in a case in which it may be important to provide a compact scanning system that might be easily storable and transportable by the user. The illumination source may thus, preferably be a constituent part of the detector and may, therefore, in particular be integrated into the detector, such as into the housing of the detector. In a preferred embodiment, particularly the housing of the scanning system may comprise at least one display configured for providing distance-related information to the user, such as in an easy-to-read manner. In a further preferred embodiment, particularly the housing of the scanning system may, in addition, comprise at least one button which may be configured for operating at least one function related to the scanning system, such as for setting one or more operation modes. In a further preferred embodiment, particularly the housing of the scanning system may, in addition, comprise at least one fastening unit which may be configured for fastening the scanning system to a further surface, such as a rubber foot, a base plate or a wall holder, such comprising as magnetic material, in particular for increasing the accuracy of the distance measurement and/or the handleablity of the scanning system by the user.

In a particularly preferred embodiment, the illumination source of the scanning system may, thus, emit a single laser beam which may be configured for the illumination of a single dot located at the surface of the object. By using at least one of the detectors according to the present invention at least one item of information about the distance between the at least one dot and the scanning system may, thus, be generated. Hereby, preferably, the distance between the illumination system as comprised by the scanning system and the single dot as generated by the illumination source may be determined, such as by employing the evaluation device as comprised by the at least one detector. However, the scanning system may, further, comprise an additional evaluation system which may, particularly, be adapted for this purpose. Alternatively or in addition, a size of the scanning system, in particular of the housing of the scanning system, may be taken into account and, thus, the distance between a specific point on the housing of the scanning system, such as a front edge or a back edge of the housing, and the single dot may, alternatively, be determined.

Alternatively, the illumination source of the scanning system may emit two individual laser beams which may be configured for providing a respective angle, such as a right angle, between the directions of an emission of the beams, whereby two respective dots located at the surface of the same object or at two different surfaces at two separate objects may be illuminated. However, other values for the respective angle between the two individual laser beams may also be feasible. This feature may, in particular, be employed for indirect measuring functions, such as for deriving an indirect distance which may not be directly accessible, such as due to a presence of one or more obstacles between the scanning system and the dot or which may otherwise be hard to reach. By way of example, it may, thus, be feasible to determine a value for a height of an object by measuring two individual distances and deriving the height by using the Pythagoras formula. In particular for being able to keep a predefined level with respect to the object, the scanning system may, further, comprise at least one leveling unit, in particular an integrated bubble vial, which may be used for keeping the predefined level by the user.

As a further alternative, the illumination source of the scanning system may emit a plurality of individual laser beams, such as an array of laser beams which may exhibit a respective pitch, in particular a regular pitch, with respect to each other and which may be arranged in a manner in order to generate an array of dots located on the at least one surface of the at least one object. For this purpose, specially adapted optical elements, such as beam-splitting devices and mirrors, may be provided which may allow a generation of the described array of the laser beams.

Thus, the scanning system may provide a static arrangement of the one or more dots placed on the one or more surfaces of the one or more objects. Alternatively, illumination source of the scanning system, in particular the one or more laser beams, such as the above described array of the laser beams, may be configured for providing one or more light beams which may exhibit a varying intensity over time and/or which may be subject to an alternating direction of emission in a passage of time. Thus, the illumination source may be configured for scanning a part of the at least one surface of the at least one object as an image by using one or more light beams with alternating features as generated by the at least one illumination source of the scanning device. In particular, the scanning system may, thus, use at least one row scan and/or line scan, such as to scan the one or more surfaces of the one or more objects sequentially or simultaneously.

In a further aspect of the present invention, a camera for imaging at least one object is disclosed. The camera comprises at least one detector according to the present invention, such as disclosed in one or more of the embodiments given above or given in further detail below. Thus, the detector may be part of a photographic device, specifically of a digital camera. Specifically, the detector may be used for 3D photography, specifically for digital 3D photography. Thus, the detector may form a digital 3D camera or may be part of a digital 3D camera. As used herein, the term “photography” generally refers to the technology of acquiring image information of at least one object. As further used herein, a “camera” generally is a device adapted for performing photography. As further used herein, the term “digital photography” generally refers to the technology of acquiring image information of at least one object by using a plurality of light-sensitive elements adapted to generate electrical signals indicating an intensity of illumination, preferably digital electrical signals. As further used herein, the term “3D photography” generally refers to the technology of acquiring image information of at least one object in three spatial dimensions. Accordingly, a 3D camera is a device adapted for performing 3D photography. The camera generally may be adapted for acquiring a single image, such as a single 3D image, or may be adapted for acquiring a plurality of images, such as a sequence of images. Thus, the camera may also be a video camera adapted for video applications, such as for acquiring digital video sequences.

Thus, generally, the present invention further refers to a camera, specifically a digital camera, more specifically a 3D camera or digital 3D camera, for imaging at least one object. As outlined above, the term imaging, as used herein, generally refers to acquiring image information of at least one object. The camera comprises at least one detector according to the present invention. The camera, as outlined above, may be adapted for acquiring a single image or for acquiring a plurality of images, such as image sequence, preferably for acquiring digital video sequences. Thus, as an example, the camera may be or may comprise a video camera. In the latter case, the camera preferably comprises a data memory for storing the image sequence.

In a further aspect of the present invention, a method for determining a position of at least one object is disclosed. The method preferably may make use of at least one detector according to the present invention, such as of at least one detector according to one or more of the embodiments disclosed above or disclosed in further detail below. Thus, for optional embodiments of the method, reference might be made to the description of the various embodiments of the detector.

The method comprises the following steps, which may be performed in the given order or in a different order. Further, additional method steps might be provided which are not listed. Further, two or more or even all of the method steps might be performed simultaneously, at least partially. Further, two or more or even all of the method steps might be performed twice or even more than twice, repeatedly.

The method according to the present invention comprises the following steps:
generating at least one longitudinal sensor signal by using at least one longitudinal optical sensor, wherein the longitudinal sensor signal is dependent on an illumination of a sensor region of the longitudinal optical sensor by a light beam, wherein the longitudinal sensor signal, given the same total power of the illumination, is dependent on a beam cross-section of the light beam in the sensor region, wherein the longitudinal optical sensor comprises at least one photodiode, the photodiode having at least two electrodes, wherein at least one photoactive layer comprising at least one electron donor material and at least one electron acceptor material is embedded between the electrodes; and
evaluating the longitudinal sensor signal of the longitudinal optical sensor by determining an item of information on the longitudinal position of the object from the longitudinal sensor signal.

For further details concerning the method according to the present invention, reference may be made to the description of the optical detector as provided above and/or below.

In a further aspect of the present invention, a use of a detector according to the present invention is disclosed. Therein, a use of the detector for a purpose of determining a position, in particular a depth, of an object is proposed, in particular, for a purpose of use selected from the group consisting of: a distance measurement, in particular in traffic technology; a position measurement, in particular in traffic technology; an entertainment application; a security application; a human-machine interface application; a tracking application; a photography application; an imaging application or camera application; a logistics application; a machine vision application; a safety application; a surveillance application; a data collection application; a mapping application for generating maps of at least one space.

Preferably, for further potential details of the optical detector, the method, the human-machine interface, the entertainment device, the tracking system, the camera and the various uses of the detector, in particular with regard to the transfer device, the longitudinal optical sensors, the evaluation device and, if applicable, to the transversal optical sensor, the modulation device, the illumination source and the imaging device, specifically with respect to the potential materials, setups and further details, reference may be made to one or more of WO 2012/110924 A1, US 2012/206336 A1, WO 2014/097181 A1, and US 2014/291480 A1, the full content of all of which is herewith included by reference.

The above-described detector, the method, the human-machine interface and the entertainment device and also the proposed uses have considerable advantages over the prior art. Thus, generally, a simple and, still, efficient detector for an accurate determining a position of at least one object in space may be provided. Therein, as an example, three-dimensional coordinates of an object or a part thereof may be determined in a fast and efficient way.

As compared to devices known in the art, the detector as proposed here may be produced by less energy-consuming and/or less time-consuming processes, in particular compared with FiP devices which employ dye-sensitized solar cells (DSC), particularly solid-state dye-sensitized solar cells (ssDSC). Thus, in principle, employing a photodiode having a photoactive layer which comprises at least one electron donor material, preferably a suitable organic polymer, and at least one electron acceptor material, preferably a fullerene-based electron acceptor material, embedded between electrodes at the sensor region of the longitudinal optical sensor in conjunction with an appropriate evaluation device is sufficient for providing an optical detector with reliable high precision position detection, which is specifically suited for machine control, such as in human-machine interfaces and, more preferably, in gaming, scanning, and tracking. Thus, cost-efficient devices may be provided which may be used for a large number of gaming, entertaining, scanning, and tracking purposes.

Further compared with FiP devices which employ dye-sensitized solar cells (DSC), similar or, even, larger ac photocurrents may be observable in the optical detector according to the present invention at comparative illumination levels. Also, similar or, even, larger sensor signals may be obtained. The same can be true for the ratio of the in-focus response vs. the out-of-focus response while the frequency response (band width) may exhibit a similar behavior. For a representative example see FIGS. 4A and 4B below.

Summarizing, in the context of the present invention, the following embodiments are regarded as particularly preferred:

### Embodiment 1

A detector for an optical detection of at least one object, comprising:
at least one longitudinal optical sensor, wherein the longitudinal optical sensor has at least one sensor region, wherein the longitudinal optical sensor is designed to generate at least one longitudinal sensor signal in a manner dependent on an illumination of the sensor region by the light beam, wherein the longitudinal sensor signal, given the same total power of the illumination, is dependent on a beam cross-section of the light beam in the sensor region, wherein the longitudinal optical sensor comprises at least one photodiode, the photodiode having at least two electrodes, wherein at least one photoactive layer comprising at least one electron donor material and at least one electron acceptor material is embedded between the electrodes; and
at least one evaluation device, wherein the evaluation device is designed to generate at least one item of information on a longitudinal position of the object by evaluating the longitudinal sensor signal.

### Embodiment 2

The detector according to the preceding embodiment, wherein the electron donor material comprises a donor polymer.

### Embodiment 3

The detector according to the preceding embodiment, wherein the electron donor material comprises an organic donor polymer.

### Embodiment 4

The detector according to the preceding embodiment, wherein the donor polymer comprises a conjugated system, wherein the conjugated system is one or more of cyclic, acyclic, and linear.

### Embodiment 5

The detector according to the preceding embodiment, wherein the organic donor polymer is one of poly(3-hexylthiophene-2,5.diyl) (P3HT), poly[3-(4-n-octyl)phenylthio-phene] (POPT), poly[3-10-n-octyl-3-phenothiazine-vinylenethiophene-co-2,5-thiophene] (PTZV-PT), poly[4,8-bis[(2-ethylhexyl)oxy] benzo[1,2-b:4,5-b]dithiophene-2,6-diyl][3-fluoro-2-[(2-ethylhexyl)carbonyl]thieno[3,4-b]thiophenediyl] (PTB7), poly{thiophene-2,5-diyl-alt-[5,6-bis(dodecyloxy)benzo[c][1,2,5]thiadiazole]-4,7-diyl} (PBT-T1), poly[2,6-(4,4-bis-(2-ethylhexyl)-4H-cyclopenta[2,1-b;3,4-b]dithiophene)-alt-4,7(2,1,3-benzothiadiazole)] (PCPDTBT), poly(5,7-bis(4-decanyl-2-thienyl)-thieno(3,4-b)diathiazolethiophene-2,5) (PDDTT), poly[N-9′-heptadecanyl-2,7-carbazole-alt-5,5-(4′,7′-di-2-thienyl-2′,1′,3′-benzothiadiazole)] (PCDTBT), poly[(4,4′-bis(2-ethylhexyl)dithieno[3,2-b;2′,3′-d]silole)-2,6-diyl-alt-(2,1,3-benzothiadiazole)-4,7-diyl] (PSBTBT), poly[3-phenylhydrazone thiophene] (PPHT), poly[2-methoxy-5-(2-ethylhexyl-oxy)-1,4-phenylenevinylene] (MEH-PPV), poly[2-methoxy-5-(2′-ethylhexyloxy)-1,4-phenylene-1,2-ethenylene-2,5-dimethoxy-1,4-phenylene-1,2-ethenylene] (M3EH-PPV), poly[2-methoxy-5-(3′,7′-dimethyloctyloxy)-1,4-phenylenevinylene] (MDMO-PPV), poly[9,9-di-octylfluorene-co-bis-N,N-4-butylphenyl-bis-N,N-phenyl-1,4-phenylenediamine] (PFB), or a derivative, a modification, or a mixture thereof.

### Embodiment 6

The detector according to any one of the preceding embodiments, wherein the electron acceptor material is a fullerene-based electron acceptor material.

### Embodiment 7

The detector according to the preceding embodiment, wherein the fullerene-based electron acceptor material comprises at least one of [6,6]-phenyl-C61-butyric acid methyl ester (PC60BM), [6,6]-Phenyl-C71-butyric acid methyl ester (PC70BM), [6,6]-phenyl C84 butyric acid methyl ester (PC84BM), an indene-C60 bisadduct (ICBA), or a derivative, a modification, or a mixture thereof.

### Embodiment 8

The detector according to any one of the two preceding embodiments, wherein the fullerene-based electron acceptor material comprises a dimer comprising one or two C60 or C70 moieties.

### Embodiment 9

The detector according to the preceding embodiment, wherein the fullerene-based electron acceptor comprises a diphenylmethanofullerene (DPM) moiety comprising one or two attached oligoether (OE) chains (C70-DPM-OE or C70-DPM-0E2, respectively).

### Embodiment 10

The detector according to any one of the preceding embodiments, wherein the electron acceptor material is one or more of tetracyanoquinodimethane (TCNQ), a perylene derivative, or inorganic nanoparticles.

### Embodiment 11

The detector according to any one of the preceding embodiments, wherein the electron acceptor material comprises an acceptor polymer.

### Embodiment 12

The detector according to the preceding embodiment, wherein the acceptor polymer comprises a conjugated polymer based on one or more of a cyanated poly(phenylene-vinylene), a benzothiadiazole, a perylene or a naphthalenediimide.

### Embodiment 13

The detector according to the preceding embodiment, wherein the acceptor polymer is selected from one or more of a cyano-poly[phenylenevinylene] (CN-PPV), poly[5-(2-(ethylhexyloxy)-2-methoxycyanoterephthalyliden] (MEH-CN-PPV), poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV), poly[1,4-dioctyloxyl-p-2,5-dicyanophenylenevinylene] (DOCN-PPV), poly[9,9′-di-octylfluoreneco-benzothiadiazole] (PF8BT), or a derivative, a modification, or a mixture thereof.

### Embodiment 14

The detector according to any one of the preceding embodiments, wherein the electron donor material and the electron acceptor material form a mixture.

### Embodiment 15

The detector according to the preceding embodiment, wherein the mixture comprises the electron donor material and the electron acceptor material in a ratio from 1:100 to 100:1, more preferred from 1:10 to 10:1, in particular of from 1:2 to 2:1.

### Embodiment 16

The detector according to any one of the preceding embodiments, wherein the electron donor material and the electron acceptor material comprise an interpenetrating network of donor and acceptor domains, interfacial areas between the donor and acceptor domains, and percolation pathways connecting the domains to the electrodes.

### Embodiment 17

The detector according to any one of the preceding embodiments, wherein the photoactive layer comprises a first layer, wherein the first layer is one of a spin-cast layer, a blade-coated layer, or a slot-coated layer.

### Embodiment 18

The detector according to any one of the preceding embodiments, wherein at least one of the electrodes is at least partially optically transparent.

### Embodiment 19

The detector according to the preceding embodiment, wherein the at least partially optically transparent electrode comprises at least one transparent conductive oxide (TCO).

### Embodiment 20

The detector according to the preceding embodiment, wherein the at least partially optically transparent electrode comprises at least one of indium-doped tin oxide (ITO), fluorine-doped tin oxide (FTO), and aluminum-doped zinc oxide (AZO).

### Embodiment 21

The detector according to any one of the three preceding embodiments, wherein an optically transparent substrate is at least partially covered with the at least partially optically transparent electrode.

### Embodiment 22

The detector according to the preceding embodiment, wherein the optically transparent substrate is selected from a glass substrate, a quartz substrate, or an optically transparent insulating polymer, in particular polyethylene terephthalate (PET).

### Embodiment 23

The detector according to any one of the preceding embodiments, wherein one of the electrodes is optically intransparent and/or reflective and comprises a metal electrode.

### Embodiment 24

The detector according to the preceding embodiment, wherein the metal electrode is one or more of a silver (Ag) electrode, a platinum (Pt) electrode, a gold (Au) electrode, and an aluminum electrode (Al).

### Embodiment 25

The detector according to the preceding embodiment, wherein the metal electrode comprises a thin layer of metal deposited onto a substrate.

### Embodiment 26

The detector according to any one of the preceding embodiments, wherein the photoactive layer is embedded between two different kinds of charge-influencing layers, wherein the two different kinds of charge-influencing layers comprise, for the same kind of charge carriers, a charge-carrier blocking layer and a charge-carrier transporting layer or, for two different kinds of charge carriers, two different charge-carrier blocking layers or two different charge-carrier transporting layers.

### Embodiment 27

The detector according to the preceding embodiment, wherein at least one of the charge-carrier blocking layer and the charge-carrier transporting layer is at least partially optically transparent and is located adjacent to the at least partially optically transparent electrode.

### Embodiment 28

The detector according to any one of the two preceding embodiments, wherein the charge-carrier blocking layer is a hole blocking layer.

### Embodiment 29

The detector according to the preceding embodiment, wherein the hole blocking layer comprises at least one of a carbonate, in particular cesium carbonate (Cs2CO3), polyethylenimine (PEI), polyethylenimine ethoxylate (PEIE), 2,9-dimethyl-4,7-diphenylphen-anthroline (BCP), (3-(4-biphenylyl)-4-phenyl-5-(4-tert-butylphenyl)-1,2,4-triazole) (TAZ).

### Embodiment 30

The detector according to any one of the two preceding embodiments, wherein the hole blocking layer comprises a transition metal oxide, in particular zinc oxide (ZnO) or titanium dioxide (TiO₂), or an alkaline fluoride, in particular lithium fluoride (LiF) or sodium fluoride (NaF).

### Embodiment 31

The detector according to any one of the five preceding embodiments, wherein the charge-carrier blocking layer is an electron blocking layer, in particular comprising a molybdenum oxide or a nickel oxide.

### Embodiment 32

The detector according to any one of the six preceding embodiments, wherein the charge-carrier transporting layer is a hole transporting layer.

### Embodiment 33

The detector according to the preceding embodiment, wherein the hole transporting layer is selected from the group consisting of a poly-3,4-ethylenedioxythiophene (PEDOT); a polyaniline (PANI); a sulfonated tetrafluoroethylene-based fluoropolymer-copolymer (Nafion), a polythiophene(PT), and a transition metal oxide.

### Embodiment 34

The detector according to the preceding embodiment, wherein the hole transporting layer is PEDOT electrically doped with at least one counter ion, in particular, PEDOT doped with sodium polystyrene sulfonate (PEDOT:PSS).

### Embodiment 35

The detector according to any one of the nine preceding embodiments, wherein at least one of the charge-carrier blocking layer and a charge-carrier transporting layer comprise a second layer, wherein the second layer is one of a spin-cast layer, a blade-coated layer, or a slot-coated layer.

### Embodiment 36

The detector according to any of the preceding embodiments, wherein the sensor region of the longitudinal optical sensor is exactly one continuous sensor region, wherein the longitudinal sensor signal is a uniform sensor signal for the entire sensor region.

### Embodiment 37

The detector according to any of the preceding embodiments, wherein the sensor region of the longitudinal optical sensor is or comprises a sensor area, the sensor area being formed by a surface of the respective device, wherein the surface faces towards the object or faces away from the object.

### Embodiment 38

The detector according to any of the preceding embodiments, wherein the optical detector is adapted to generate the longitudinal sensor signal by one or more of measuring an electrical resistance or a conductivity of at least one part of the sensor region.

### Embodiment 39

The detector according to the preceding embodiment, wherein the optical detector is adapted to generate the longitudinal sensor signal by performing at least one current-voltage measurement and/or at least one voltage-current-measurement.

### Embodiment 40

The detector according to any of the preceding embodiments, wherein the evaluation device is designed to generate the at least one item of information on the longitudinal position of the object from at least one predefined relationship between the geometry of the illumination and a relative positioning of the object with respect to the detector, preferably taking account of a known power of the illumination and optionally taking account of a modulation frequency with which the illumination is modulated.

### Embodiment 41

The detector according to any of the preceding embodiments, wherein the evaluation device is adapted to normalize the longitudinal sensor signals and to generate the information on the longitudinal position of the object independent from an intensity of the light beam.

### Embodiment 42

The detector according to the preceding embodiment, wherein the evaluation device is adapted to recognize whether the light beam widens or narrows, by comparing the longitudinal sensor signals of different longitudinal sensors.

### Embodiment 43

The detector according to any of the preceding embodiments, wherein the evaluation device is adapted to generate the at least one item of information on the longitudinal position of the object by determining a diameter of the light beam from the at least one longitudinal sensor signal.

### Embodiment 44

The detector according to the preceding embodiment, wherein the evaluation device is adapted to compare the diameter of the light beam with known beam properties of the light beam in order to determine the at least one item of information on the longitudinal position of the object, preferably from a known dependency of a beam diameter of the light beam on at least one propagation coordinate in a direction of propagation of the light beam and/or from a known Gaussian profile of the light beam.

### Embodiment 45

The detector according to any of the preceding embodiments, wherein the detector furthermore has at least one modulation device for modulating the illumination.

### Embodiment 46

The detector according to any the preceding embodiment, wherein the light beam is a modulated light beam.

### Embodiment 47

The detector according to the preceding embodiment, wherein the detector is designed to detect at least two longitudinal sensor signals in the case of different modulations, in particular at least two sensor signals at respectively different modulation frequencies, wherein the evaluation device is designed to generate the at least one item of information on the longitudinal position of the object by evaluating the at least two longitudinal sensor signals.

### Embodiment 48

The detector according to any of the preceding embodiments, wherein the longitudinal optical sensor is furthermore designed in such a way that the longitudinal sensor signal, given the same total power of the illumination, is dependent on a modulation frequency of a modulation of the illumination.

### Embodiment 49

The detector according to any one of the preceding embodiments, furthermore comprising at least one illumination source.

### Embodiment 50

The detector according to the preceding embodiment, wherein the illumination source is selected from: an illumination source, which is at least partly connected to the object and/or is at least partly identical to the object; an illumination source which is designed to at least partly illuminate the object with a primary radiation.

### Embodiment 51

The detector according to the preceding embodiment, wherein the light beam is generated by a reflection of the primary radiation on the object and/or by light emission by the object itself, stimulated by the primary radiation.

### Embodiment 52

The detector according to the preceding embodiment, wherein the spectral sensitivities of the longitudinal optical sensor is covered by the spectral range of the illumination source.

### Embodiment 53

The detector according to any of the preceding embodiments, wherein the detector has at least two longitudinal optical sensors, wherein the longitudinal optical sensors are stacked.

### Embodiment 54

The detector according to the preceding embodiment, wherein the longitudinal optical sensors are stacked along the optical axis.

### Embodiment 55

The detector according to any of the two preceding embodiments, wherein the longitudinal optical sensors form a longitudinal optical sensor stack, wherein the sensor regions of the longitudinal optical sensors are oriented perpendicular to the optical axis.

### Embodiment 56

The detector according to any of the three preceding embodiments, wherein the longitudinal optical sensors are arranged such that a light beam from the object illuminates all longitudinal optical sensors, preferably sequentially, wherein at least one longitudinal sensor signal is generated by each longitudinal optical sensor.

### Embodiment 57

The detector according to any of the preceding embodiments, wherein the at least one longitudinal optical sensor comprises at least one transparent longitudinal optical sensor.

### Embodiment 58

The detector according to any one of the preceding embodiments, further comprising at least one transversal optical sensor, the transversal optical sensor being adapted to determine a transversal position of the light beam traveling from the object to the detector, the transversal position being a position in at least one dimension perpendicular to an optical axis of the detector, the transversal optical sensor being adapted to generate at least one transversal sensor signal, wherein the evaluation device is further designed to generate at least one item of information on a transversal position of the object by evaluating the transversal sensor signal.

### Embodiment 59

The detector according to the preceding embodiment, wherein the transversal optical sensor is a photo detector having at least one first electrode, at least one second electrode and at least one photoconductive material embedded in between two separate layers of a transparent conductive oxide, wherein the transversal optical sensor has a sensor area, wherein the first electrode and the second electrode are applied to different locations of one of the layers of the transparent conductive oxide, wherein the at least one transversal sensor signal indicates a position of the light beam in the sensor area.

### Embodiment 60

The detector according to any of the two preceding embodiments, wherein the at least one transversal optical sensor comprises at least one transparent transversal optical sensor.

### Embodiment 61

The detector according to any of the three preceding embodiments, wherein the sensor area of the transversal optical sensor is formed by a surface of the transversal optical sensor, wherein the surface faces towards the object or faces away from the object.

### Embodiment 62

The detector according to any of the four preceding embodiments, wherein the first electrode and/or the second electrode are a split electrode comprising at least two partial electrodes.

### Embodiment 63

The detector according to the preceding embodiments, wherein at least four partial electrodes are provided.

### Embodiment 64

The detector according to any one of the two preceding embodiments, wherein electrical currents through the partial electrodes are dependent on a position of the light beam in the sensor area.

### Embodiment 65

The detector according to the preceding embodiment, wherein the transversal optical sensor is adapted to generate the transversal sensor signal in accordance with the electrical currents through the partial electrodes.

### Embodiment 66

The detector according to any of the two preceding embodiments, wherein the detector, preferably the transversal optical sensor and/or the evaluation device, is adapted to derive the information on the transversal position of the object from at least one ratio of the currents through the partial electrodes.

### Embodiment 67

The detector according to any of the fourteen preceding embodiments, wherein the at least one transversal optical sensor is a transparent optical sensor.

### Embodiment 68

The detector according to any of the ten preceding embodiments, wherein the transversal optical sensor and the longitudinal optical sensor are stacked along the optical axis such that a light beam travelling along the optical axis both impinges the transversal optical sensor and the at least two longitudinal optical sensors.

### Embodiment 69

The detector according to the preceding embodiment, wherein the light beam subsequently passes through the transversal optical sensor and the at least two longitudinal optical sensors or vice versa.

### Embodiment 70

The detector according to the preceding embodiment, wherein the light beam passes through the transversal optical sensor before impinging on one of the longitudinal optical sensors.

### Embodiment 71

The detector according to any of the twelve preceding embodiments, wherein the transversal sensor signal is selected from the group consisting of a current and a voltage or any signal derived thereof.

### Embodiment 72

The detector according to any one of the preceding embodiments, wherein the detector further comprises at least one imaging device.

### Embodiment 73

The detector according to the preceding claim, wherein the imaging device is located in a position furthest away from the object.

### Embodiment 74

The detector according to any of the two preceding embodiments, wherein the light beam passes through the at least one longitudinal optical sensor before illuminating the imaging device.

### Embodiment 75

The detector according to any of the three preceding embodiments, wherein the imaging device comprises a camera.

### Embodiment 76

The detector according to any of the four preceding embodiments, wherein the imaging device comprises at least one of: an inorganic camera; a monochrome camera; a multichrome camera; a full-color camera; a pixelated inorganic chip; a pixelated organic camera; a CCD chip, preferably a multi-color CCD chip or a full-color CCD chip; a CMOS chip; an IR camera; an RGB camera.

### Embodiment 77

An arrangement comprising at least two detectors according to any of the preceding embodiments.

### Embodiment 78

The arrangement according to any of the two preceding embodiments, wherein the arrangement further comprises at least one illumination source.

### Embodiment 79

A human-machine interface for exchanging at least one item of information between a user and a machine, in particular for inputting control commands, wherein the human-machine interface comprises at least one detector according to any of the preceding embodiments relating to a detector, wherein the human-machine interface is designed to generate at least one item of geometrical information of the user by means of the detector wherein the human-machine interface is designed to assign to the geometrical information at least one item of information, in particular at least one control command.

### Embodiment 80

The human-machine interface according to the preceding embodiment, wherein the at least one item of geometrical information of the user is selected from the group consisting of: a position of a body of the user; a position of at least one body part of the user; an orientation of a body of the user; an orientation of at least one body part of the user.

### Embodiment 81

The human-machine interface according to any of the two preceding embodiments, wherein the human-machine interface further comprises at least one beacon device connectable to the user, wherein the human-machine interface is adapted such that the detector may generate an information on the position of the at least one beacon device.

### Embodiment 82

The human-machine interface according to the preceding embodiment, wherein the beacon device comprises at least one illumination source adapted to generate at least one light beam to be transmitted to the detector.

### Embodiment 83

An entertainment device for carrying out at least one entertainment function, in particular a game, wherein the entertainment device comprises at least one human-machine interface according to any of the preceding embodiments referring to a human-machine interface, wherein the entertainment device is designed to enable at least one item of information to be input by a player by means of the human-machine interface, wherein the entertainment device is designed to vary the entertainment function in accordance with the information.

### Embodiment 84

A tracking system for tracking the position of at least one movable object, the tracking system comprising at least one detector according to any of the preceding embodiments referring to a detector, the tracking system further comprising at least one track controller, wherein the track controller is adapted to track a series of positions of the object, each comprising at least one item of information on a position of the object at a specific point in time.

### Embodiment 85

The tracking system according to the preceding embodiment, wherein the tracking system further comprises at least one beacon device connectable to the object, wherein the tracking system is adapted such that the detector may generate an information on the position of the object of the at least one beacon device.

### Embodiment 86

A scanning system for determining at least one position of at least one object, the scanning system comprising at least one detector according to any of the preceding embodiments relating to a detector, the scanning system further comprising at least one illumination source adapted to emit at least one light beam configured for an illumination of at least one dot located at at least one surface of the at least one object, wherein the scanning system is designed to generate at least one item of information about the distance between the at least one dot and the scanning system by using the at least one detector.

### Embodiment 87

The scanning system according to the preceding embodiment, wherein the illumination source comprises at least one artificial illumination source, in particular at least one laser source and/or at least one incandescent lamp and/or at least one semiconductor light source.

### Embodiment 88

The scanning system according to any one of the two preceding embodiments, wherein the illumination source emits a plurality of individual light beams, in particular an array of light beams exhibiting a respective pitch, in particular a regular pitch.

### Embodiment 89

The scanning system according to any one of the three preceding embodiments, wherein the scanning system comprises at least one housing.

### Embodiment 90

The scanning system according to the preceding embodiment, wherein the at least one item of information about the distance between the at least one dot and the scanning system distance is determined between the at least one dot and a specific point on the housing of the scanning system, in particular a front edge or a back edge of the housing.

### Embodiment 91

The scanning system according to any one of the two preceding embodiments, wherein the housing comprises at least one of a display, a button, a fastening unit, a leveling unit.

### Embodiment 92

A camera for imaging at least one object, the camera comprising at least one detector according to any one of the preceding embodiments referring to a detector.

### Embodiment 93

A method for an optical detection of at least one object, in particular using a detector according to any of the preceding embodiments relating to a detector, comprising the following steps:
generating at least one longitudinal sensor signal by using at least one longitudinal optical sensor, wherein the longitudinal sensor signal is dependent on an illumination of a sensor region of the longitudinal optical sensor by a light beam, wherein the longitudinal sensor signal, given the same total power of the illumination, is dependent on a beam cross-section of the light beam in the sensor region, wherein the longitudinal optical sensor comprises at least one photodiode, the photodiode having at least two electrodes, wherein at least one photoactive layer comprising at least one electron donor material and at least one electron acceptor material is embedded between the electrodes; and
evaluating the longitudinal sensor signal of the longitudinal optical sensor by determining an item of information on the longitudinal position of the object from the longitudinal sensor signal.

### Embodiment 94

The use of a detector according to any of the preceding embodiments relating to a detector for a purpose of determining a position, in particular a depth of an object.

### Embodiment 95

The use of a detector according to the previous embodiment, for a purpose of use, selected from the group consisting of: a distance measurement, in particular in traffic technology; a position measurement, in particular in traffic technology; an entertainment application; a security application; a human-machine interface application; a scanning application, a tracking application; a logistics application; a machine vision application; a safety application; a surveillance application; a data collection application; a photography application; an imaging application or camera application; a mapping application for generating maps of at least one space.

### BRIEF DESCRIPTION OF THE FIGURES

Further optional details and features of the invention are evident from the description of preferred exemplary embodiments which follows in conjunction with the dependent claims. In this context, the particular features may be implemented alone or with features in combination. The invention is not restricted to the exemplary embodiments. The exemplary embodiments are shown schematically in the figures. Identical reference numerals in the individual figures refer to identical elements or elements with identical function, or elements which correspond to one another with regard to their functions.

Specifically, in the figures:

FIG. 1 illustrates an exemplary embodiment of an optical detector according to the present invention comprising at least one longitudinal optical sensor;

FIG. 2 shows a particularly preferred embodiment of a photodiode comprised in a sensor region of the longitudinal optical sensor according to the present invention;

FIG. 3 shows an experimental diagram presenting the current density vs. voltage characteristics of the optical detector under illumination;

FIG. 4A and 4B depict the photocurrent vs. distance between the longitudinal optical sensor and the object (FIG. 4A) and the photocurrent vs. frequency of a modulation for different focus conditions (FIG. 4B); and

FIG. 5 shows an exemplary embodiment of the optical detector and of a detector system, a human-machine interface, an entertainment device, a tracking system, and a camera, each comprising the optical detector according to the present invention.

### EXEMPLARY EMBODIMENTS

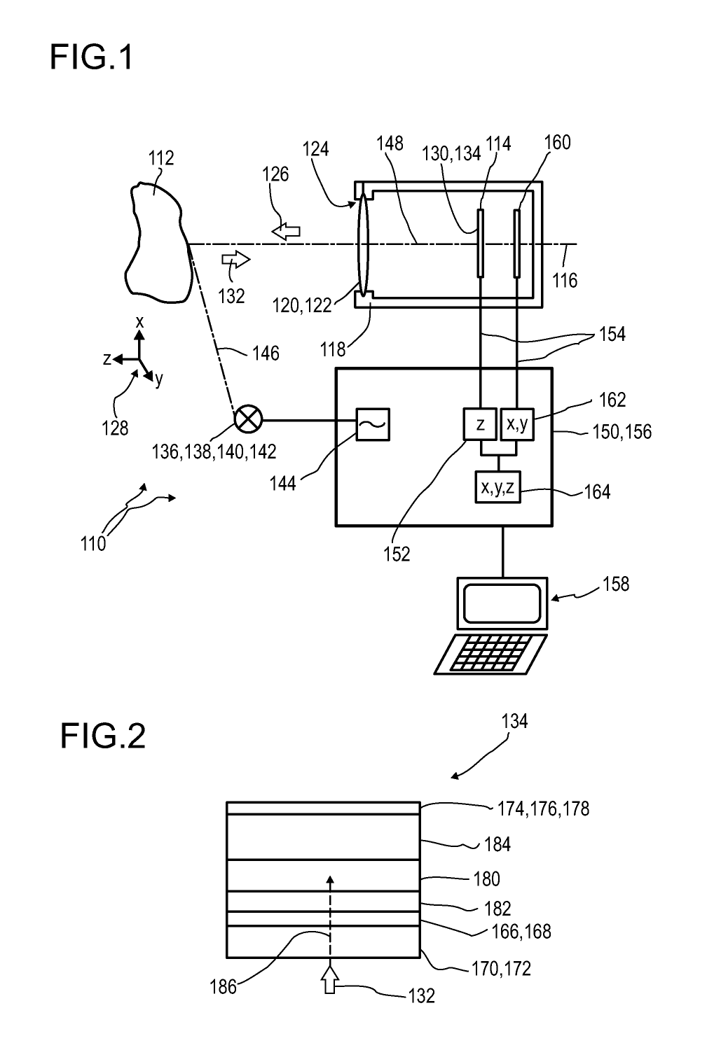

FIG. 1 illustrates, in a highly schematic illustration, an exemplary embodiment of an optical detector 110 according to the present invention, for determining a position of at least one object 112. However, other embodiments are feasible.

The optical detector 110 comprises at least one longitudinal optical sensor 114, which, in this particular embodiment, is arranged along an optical axis 116 of the detector 110. Specifically, the optical axis 116 may be an axis of symmetry and/or rotation of the setup of the optical sensors 114. The optical sensors 114 may be located inside a housing 118 of the detector 110. Further, at least one transfer device 120 may be comprised, preferably a refractive lens 122. An opening 124 in the housing 118, which may, particularly, be located concentrically with regard to the optical axis 116, preferably defines a direction of view 126 of the detector 110. A coordinate system 128 may be defined, in which a direction parallel or antiparallel to the optical axis 116 is defined as a longitudinal direction, whereas directions perpendicular to the optical axis 116 may be defined as transversal directions. In the coordinate system 128, symbolically depicted in FIG. 1, a longitudinal direction is denoted by “z” and transversal directions are denoted by “x” and “y”, respectively. However, other types of coordinate systems 128 are feasible.

Further, the longitudinal optical sensor 114 is designed to generate at least one longitudinal sensor signal in a manner dependent on an illumination of a sensor region 130 by a light beam 132. Thus, according to the FiP effect, the longitudinal sensor signal, given the same total power of the illumination, is dependent on a beam cross-section of the light beam 132 in the respective sensor region 130, as will be outlined in further detail below. According to the present invention, the sensor region 130 of the longitudinal optical 110 sensor comprises at least one photodiode 134, in particular in a preferred embodiment which is described in FIG. 2 in more detail.

The light beam 132 for illumining the sensor region 130 of the longitudinal optical sensor 114 may be generated by a light-emitting object 112. Alternatively or in addition, the light beam 132 may be generated by a separate illumination source 136, which may include an ambient light source and/or an artificial light source 138, such as a light-emitting diode 140, being adapted to illuminate the object 112 that the object 112 may be able to reflect at least a part of the light generated by the illumination source 136 in a manner that the light beam 132 may be configured to reach the sensor region 130 of the longitudinal optical sensor 114, preferably by entering the housing 118 of the optical detector 110 through the opening 124 along the optical axis 116.

In a specific embodiment, the illumination source 136 may be a modulated light source 142, wherein one or more modulation properties of the illumination source may be controlled by at least one modulation device 144. Alternatively or in addition, the modulation may be effected in a first beam path 146 between the illumination source and the object 112 and/or in a second beam path 148 between the object 112 and the longitudinal optical sensor 114. Further possibilities may be conceivable. In this specific embodiment, it may be advantageous taking into account one or more of the modulation properties, in particular the modulation frequency, when evaluating the sensor signal of the transversal optical sensor 114 for determining the at least one item of information on the position of the object 112.

The evaluation device 150 is, generally, designed to generate at least one item of information on a position of the object 112 by evaluating the sensor signal of the longitudinal optical sensor 114. For this purpose, the evaluation device 150 may comprise one or more electronic devices and/or one or more software components, in order to evaluate the sensor signals, which are symbolically denoted by a longitudinal evaluation unit 152 (denoted by “z”). As will be explained below in more detail, the evaluation device 150 may be adapted to determine the at least one item of information on the longitudinal position of the object 112 by comparing more than one longitudinal sensor signals of the longitudinal optical sensor 114. As explained above, the longitudinal sensor signal as provided by the longitudinal optical sensor 114 upon impingement by the light beam 132 depends on an illumination of the sensor region 130 by the light beam 132, wherein the longitudinal sensor signal, given the same total power of the illumination, is dependent on a beam cross-section of the light beam 132 in the sensor region 130. As for example explained in WO 2012/110924 A1 in more detail, the evaluation device 150 may be adapted to determine the at least one item of information on the longitudinal position of the object 112 by comparing more than one longitudinal sensor signals of the longitudinal optical sensor 114.

Generally, the evaluation device 150 may be part of a data processing device and/or may comprise one or more data processing devices. The evaluation device may be fully or partially integrated into the housing 118 and/or may fully or partially be embodied as a separate device which is electrically connected in a wireless or wire-bound fashion, such as via one or more signal leads 154, to the longitudinal optical sensor 114. The evaluation device may further comprise one or more additional components, such as one or more electronic hardware components and/or one or more software components, such as one or more measurement units and/or one or more evaluation units (not depicted in FIG. 1) and/or one or more controlling units, such as the modulation device 144 being adapted to control the modulation properties of the modulated light source 142. Further, the evaluation device 150 may be a computer 156 and/or may comprise a computer system comprising a data processing device 158. However, other embodiments are feasible.

In a preferred embodiment, the optical detector 110 further comprises at least one transversal optical sensor 160 which, in this particular embodiment, is also arranged along an optical axis 116 of the detector 110. Herein, the transversal optical sensor 160 may, preferably, be adapted to determine a transversal position of the light beam 132 traveling from the object 112 to the optical detector 110. Herein, the transversal position may be a position in at least one dimension perpendicular an optical axis 116 of the optical detector 110, in this particular embodiment denoted by “x” and “y”, respectively, according to the coordinate system 128. The transversal optical sensor 160 may further be adapted to generate at least one transversal sensor signal. The transversal sensor signal may be transmitted in a wireless or wire-bound fashion, such as via one or more signal leads 154, to the evaluation device 150, which may further be designed to generate at least one item of information on a transversal position of the object 112 by evaluating the transversal sensor signal. For this purpose, the evaluation device 150 may further comprise one or more electronic devices and/or one or more software components, in order to evaluate the sensor signals, which are symbolically denoted by a transversal evaluation unit 162 (denoted by “z”). Further, by combining results derived by the evolution units 152, 162, a position information 164, preferably a three-dimensional position information, symbolically denoted here by “x, y, z”, may thus be generated.

The optical detector 110 may have a straight beam path or a tilted beam path, an angulated beam path, a branched beam path, a deflected or split beam path or other types of beam paths. Further, the light beam 132 may propagate along each beam path or partial beam path once or repeatedly, unidirectionally or bidirectionally. Thereby, the components listed above or the optional further components listed in further detail below may fully or partially be located in front of the longitudinal optical sensors 114 and/or behind the longitudinal optical sensors 114.

FIG. 2 shows a particularly preferred embodiment of the photodiode 134 within the sensor region 130 of the longitudinal optical sensor 110 according to the present invention.

As schematically depicted, the photodiode 134 has an optically transparent first electrode 166. Preferably, the photodiode 134 may be arranged in a manner that the optically transparent first electrode 166 may be located towards the incident light beam 132. The optically transparent first electrode 166 may comprise a layer of one or more transparent conductive oxides 168 (TCO), in particular indium-doped tin oxide (ITO). However, other kinds of optically transparent materials, such as fluorine-doped tin oxide (FTO) or aluminum-doped zinc oxide (AZO), may also be suitable for this purpose. In order to be able to using a minimum of the optically transparent oxide 168 but still keep the optically transparent first electrode 166 mechanically stable, the optically transparent oxide 168 may be placed on top of an optically transparent substrate 170, in particular on top of a glass substrate 172, preferably by using a deposition method, such as a coating or an evaporation method. Alternatively, a quartz substrate or a substrate comprising an optically transparent but electrically insulating polymer, such as poly-3,4-ethylenedioxythiophene (PEDOT) or polyethylene terephthalate (PET), may also be used for this purpose.

Further, the photodiode 134 has a second electrode 174, which may be optically intransparent. Accordingly, the photodiode 134 may be arranged in a manner that the optically intransparent second electrode 174 may be located away from the incident light beam 132. In this preferred embodiment, the second electrode 174 may comprise a metal electrode 176, such as a silver (Ag) electrode, a platinum (Pt) electrode, a gold (Au) electrode, or an aluminum electrode (Al). Preferably, the metal electrode 176 may comprise a thin layer of metal 178 which may be deposited onto a substrate, such as a further layer.

Further, the photodiode 134 has at least one photoactive layer 180 which comprises at least one electron donor material, preferably an organic polymer, and at least one electron acceptor material, preferably a fullerene-based electron acceptor material. In his particularly preferred example, the photoactive layer 180 comprises a blend of poly(3-hexylthiophene-2,5-diyl) (P3HT) as the organic polymer which may constitute the electron donor material and of [6,6]-phenyl-C61-butyric acid methyl ester (PC60BM) which may be employed as the fullerene-based electron acceptor material, wherein the blend of P3HT and PC60BM exhibits a ratio of 1:1. However, other kinds of electron donor materials and electron acceptor materials, in particular the materials as mentioned elsewhere in this application, as well as other ratios between two or more constituents of the blend may be used, mainly depending on the purposes of the optical detector 110.

According to the present invention, the photoactive layer 180 is embedded between the first electrode 166 and the second electrode 174. However, in this preferred embodiment, the photoactive layer may be embedded between a charge-carrier blocking layer 182 and a charge-carrier transporting layer 184 in a manner that the charge-carrier blocking layer 182 may further adjoin the first electrode 166 while the charge-carrier transporting layer 184 may additionally adjoin the second electrode 174. Alternatively, two different kinds of charge-carrier blocking layers 182 may be present in order to embed the photoactive layer 180. Herein, a first charge-carrier blocking layer may be a hole blocking layer while a second charge-carrier blocking layer may be an electron blocking layer. Herein, the electron blocking layer may be capable of achieving a similar effect as a hole transporting layer when embedding the photoactive layer. Again, in order to allow the incident light beam 132 reaching the photoactive layer 180, the charge-carrier blocking layer 182 may, preferably, be an optically transparent layer, such that the light beam 132, which impinges on the photodiode 134, may follow a beam path 186 within the photodiode through the optically transparent substrate 170, the optically transparent first electrode 166, and the optically transparent charge-carrier blocking layer 182 until it may arrive at the photoactive layer 180 as desired. However, other arrangements of the mentioned constituents within the photodiode 134, which may still allow the incident light beam 132 to at least partially reach the photoactive layer 180, may also be feasible.

In the preferred embodiment depicted in FIG. 2, the charge-carrier blocking layer may be a hole blocking layer which comprises a hole blocking material. Preferably, the hole blocking material may be selected to comprise polyethylenimine ethoxylate (PEIE) or a transition metal oxide, in particular ZnO, or a mixture thereof. However, other kinds of hole blocking materials, in particular the materials as mentioned elsewhere in this application, may be employed for this purpose. Herein, the thickness of the hole blocking layer may, preferably, be in a range to allow a significant short-cut current through the hole blocking layer under illumination of the photodiode 134, in particular in the range from 1 nm to 100 nm.

Further, the charge-carrier transporting layer may be a hole transporting layer which comprises a hole transporting material. Preferably, the hole transporting layer may be layer of poly-3,4-ethylenedioxythiophene (PEDOT), preferably, wherein the PEDOT may be electrically doped with at least one counter ion in particular, wherein the PEDOT may be doped with sodium polystyrene sulfonate (PEDOT:PSS). However, also here other kinds of hole transporting materials, in particular the materials as mentioned elsewhere in this application, may be used for this purpose.

A particular advantage of the setup of the photodiode 134 as schematically depicted in FIG. 2 may be attributed to an observation that one or more, preferably all, of the photoactive layer 180, the charge-carrier blocking layer 182, and the charge-carrier transporting layer 184 may be provided by using a deposition method, preferably by a coating method, more preferred by a spin-coating method or slot-coating method. Further, one or more of the electrodes 166, 174 within the photodiode 134 may be produced by depositing the respective electrode material onto a corresponding substrate by using a suitable deposition method, such as a coating or evaporation method. Consequently and in contrast to a dye-sensitized solar cell (DSC), preferably a solid-state dye-sensitized solar cell (ssDSC), an application of deposition methods does not require one or more annealing steps. By using an appropriate organic polymer, the maximum temperature as required for this kind of production methods may be selected to be below 140° C., below 120° C., below 100° C., or less, depending on the choice of the organic polymer in the photoactive layer 180. In addition, the application of the deposition methods allows a faster and energy-saving production of the photodiodes 134 since, generally, the deposition methods require less time and energy compared to time- and energy-consuming annealing processes.

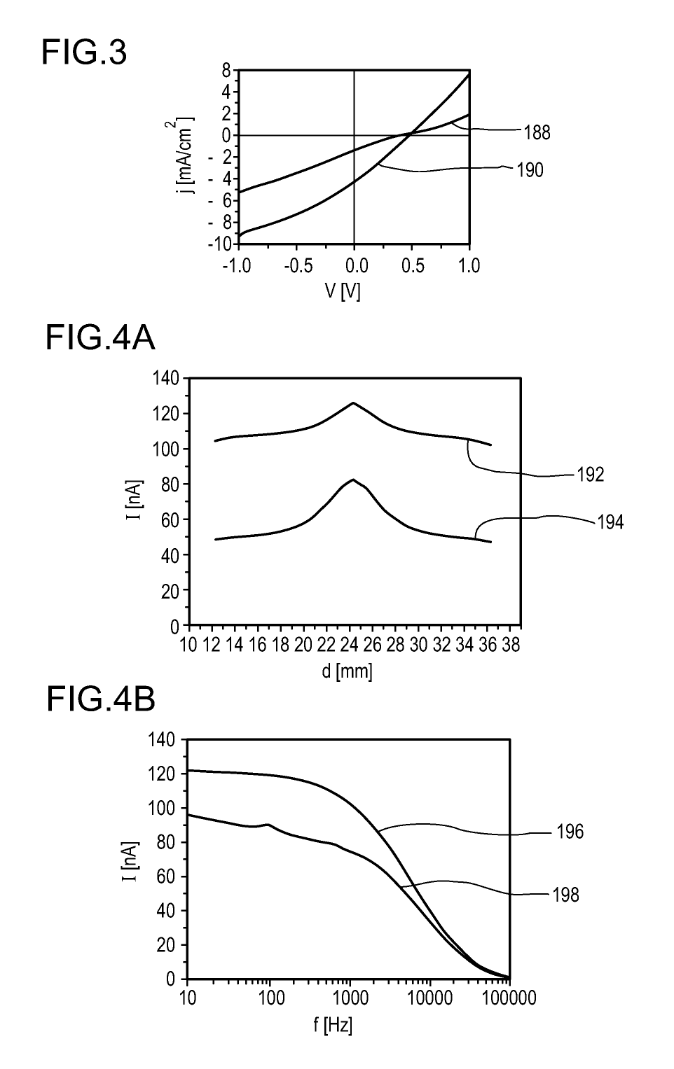

FIG. 3 shows an experimental diagram which presents the steady-state current density j vs. voltage V characteristic of the optical detector 110 according to the present invention under illumination by an incident light beam 132. Herein, a first curve 188 relates to a first embodiment in which the photodiode 134 comprises PEIE as the hole blocking material 182 while a second curve 190 relates to a second embodiment in which the photodiode 134 comprises a mixture of ZnO and PEIE as the hole blocking material 182. However, in both cases, the photodiode 134 comprises ITO on the glass substrate 172 as the first electrode 166, the blend of P3HT and PC60BM as the photoactive layer 180, PEDOT as the hole transporting layer 184, and a silver layer as the second electrode 174. Alternatively, instead of using the hole transporting layer 184 an electron blocking layer, such as a molybdenum oxide or a nickel oxide, may be used. From FIG. 3 it may be derived that a photocurrent which is generated and extracted in the fourth quadrant as shown in FIG. 3, i.e. the quadrant where both the voltage and the steady-state current density exceed a value of zero, is known to be characteristic for a solar cell.

Surprisingly, as depicted in FIGS. 4A and 4B, the FiP effect may be observable in the optical detector 110 according to the present invention. In these experimental diagrams, an alternating current (ac) photocurrent I vs. a distance d of the longitudinal optical sensor 114 from the object 112 (FIG. 4A) and the ac photocurrent I vs. the frequency f of the modulated illumination source 142 for different focus conditions (FIG. 4B) are respectively shown.

As can be derived from FIG. 4A, both a first curve 192 and a second curve 194 clearly exhibit a positive FiP effect. Herein, the first curve 192 relates to the first embodiment as described in relationship to FIG. 3 in which the photodiode 134 comprises PEIE as the hole blocking material 182 while the second curve 194, again, relates to the second embodiment related to FIG. 3 in which the photodiode 134 comprises a mixture of ZnO and PEIE as the hole blocking material 182. Consequently, the ac photocurrent at short circuit conditions shows a characteristic maximum when a condition that the incident light beam 132 is focused onto the sensor region 130 of the longitudinal optical sensor 114 is fulfilled. In this particular example, the condition is fulfilled around a distance of approximately 24 mm between the longitudinal optical sensor 114 and the object 112 in the direction of view 126. For recording both the first curve 192 and the second curve 194 in FIG. 4A, the illumination source 136 has been modulated with the frequency of 375 Hz. As the modulated illumination source 142 a light-emitting diode 140 providing green light, i.e. a wavelength of the light beam 132 of 530 nm, has been employed.

In a further embodiment (not depicted here), other kinds of electron donor materials may also be suitable, in particular polymers being sensitive in the infrared spectral range, especially in the NIR range above 1000 nm, preferably diketopyrrolopyrrol polymers, in particular, the polymers as described in EP 2 818 493 A1, more preferably the polymers denoted as “P-1” to “P-10” therein; benzodithiophene polymers as disclosed in WO 2014/086722 A1, especially diketo-pyrrolopyrrol polymers comprising benzodithiophene units; dithienobenzofuran polymers according to US 2015/132887 A1, especially dithienobenzofuran polymers comprising diketo-pyrrolopyrrol units; phenantro[9, 10-B]furan polymers as described in US 2015/0111337 A1, especially phenantro [9, 10-B] furan polymers which comprise diketopyrrolopyrrol units; and polymer compositions comprising diketopyrrolopyrrol oligomers, in particular, in an oligomer-polymer ratio of 1:10 or 1:100, such as disclosed in US 2014/0217329 A1. As could be verified experimentally, the photodiodes 134 comprising these kinds of polymers in the photoactive layer 180, exhibit the desired negative FiP effect in the NIR range, particularly above 1000 nm.

As indicated above, FIG. 4B shows the ac photocurrent vs. the frequency of the modulated illumination source 142 at short-circuit conditions for an in-focus condition 196 and an out-of-focus condition 198, respectively. For both curves, the first embodiment as described in relationship to FIG. 3 in which the photodiode 134 comprises PEIE as the hole blocking material 182 has been used. As can be derived from FIG. 4B, a ratio between both curves at a selected frequency indicates that the optical detector according to the present invention which comprises the longitudinal optical sensor 114 having the photoactive layer 180 comprising the blend of the organic polymer and the fullerene-based electron acceptor material is suitable for being used in a distance sensor as well as, by further employing one or more of the transversal optical sensors 160, in a 3-dimensional sensor which are based on the FiP technology, in particular, known from WO 2012/110924 A1 and WO 2014/097181 A1.

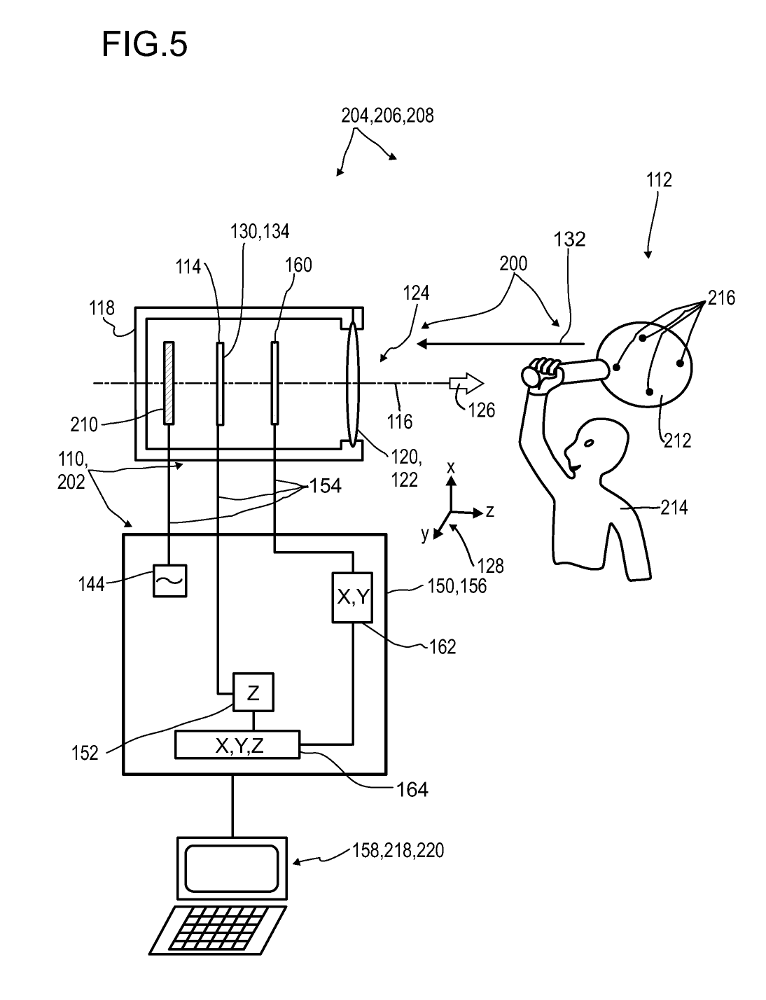

As an example, FIG. 5 shows an exemplary embodiment of a detector system 200, comprising at least one optical detector 110, such as the optical detector 110 as disclosed in one or more of the embodiments shown in FIGS. 1 to 4. Herein, the optical detector 110 may be employed as a camera 202, specifically for 3D imaging, which may be made for acquiring images and/or image sequences, such as digital video clips. Further, FIG. 5 shows an exemplary embodiment of a human-machine interface 204, which comprises the at least one detector 110 and/or the at least one detector system 200, and, further, an exemplary embodiment of an entertainment device 206 comprising the human-machine interface 204. FIG. 5 further shows an embodiment of a tracking system 208 adapted for tracking a position of at least one object 112, which comprises the detector 110 and/or the detector system 200.

With regard to the optical detector 110 and to the detector system 200, reference may be made to the full disclosure of this application. Basically, all potential embodiments of the detector 110 may also be embodied in the embodiment shown in FIG. 5. The evaluation device may be connected to each of the at least two longitudinal optical sensors, in particular, by the signal leads 154. As described above, a use of two or, preferably, three longitudinal optical sensors 114 may support the evaluation of the longitudinal sensor signals without any remaining ambiguity. The evaluation device 150 may further be connected to the at least one optional transversal optical sensor 160, in particular, by the signal leads 154. By way of example, the signal leads 154 may be provided and/or one or more interfaces, which may be wireless interfaces and/or wire-bound interfaces. Further, the signal leads 154 may comprise one or more drivers and/or one or more measurement devices for generating sensor signals and/or for modifying sensor signals. Further, again, the at least one transfer device 120 may be provided, in particular as the refractive lens 122 or convex mirror. The optical detector 110 may further comprise the at least one housing 118 which, as an example, may encase one or more of components.

Further, the evaluation device 150 may fully or partially be integrated into the optical sensors and/or into other components of the optical detector 110. The evaluation device 150 may also be enclosed into the housing 118 and/or into a separate housing. The evaluation device 150 may comprise one or more electronic devices and/or one or more software components, in order to evaluate the sensor signals, which are symbolically denoted by the longitudinal evaluation unit 152 (denoted by “z”) and a transversal evaluation unit 162 (denoted by “x y”). By combining results derived by these evolution units, a position information 164, preferably a three-dimensional position information, may be generated (denoted by “x y z”).

Further, the optical detector 110 and/or to the detector system 200 may comprise an imaging device 210 which may be configured in various ways. Thus, as depicted in FIG. 5, the imaging device can for example be part of the detector 110 within the detector housing 118. Herein, the imaging device signal may be transmitted by one or more signal leads 154 to the evaluation device 150 of the detector 110. Alternatively, the imaging device 210 may be separately located outside the detector housing 118. The imaging device 210 may be fully or partially transparent or intransparent. The imaging device 210 may be or may comprise an organic imaging device or an inorganic imaging device. Preferably, the imaging device 210 may comprise at least one matrix of pixels, wherein the matrix of pixels may particularly be selected from the group consisting of: an inorganic semiconductor sensor device such as a CCD chip and/or a CMOS chip; an organic semiconductor sensor device.

In the exemplary embodiment as shown in FIG. 5, the object 112 to be detected, as an example, may be designed as an article of sports equipment and/or may form a control element 212, the position and/or orientation of which may be manipulated by a user 214. Thus, generally, in the embodiment shown in FIG. 5 or in any other embodiment of the detector system 200, the human-machine interface 204, the entertainment device 206 or the tracking system 208, the object 112 itself may be part of the named devices and, specifically, may comprise the at least one control element 212, specifically, wherein the at least one control element 212 has one or more beacon devices 216, wherein a position and/or orientation of the control element 212 preferably may be manipulated by user 214. As an example, the object 112 may be or may comprise one or more of a bat, a racket, a club or any other article of sports equipment and/or fake sports equipment. Other types of objects 112 are possible. Further, the user 214 may be considered as the object 112, the position of which shall be detected. As an example, the user 214 may carry one or more of the beacon devices 216 attached directly or indirectly to his or her body.

The optical detector 110 may be adapted to determine at least one item on a longitudinal position of one or more of the beacon devices 216 and, optionally, at least one item of information regarding a transversal position thereof, and/or at least one other item of information regarding the longitudinal position of the object 112 and, optionally, at least one item of information regarding a transversal position of the object 112. Particularly, the optical detector 110 may be adapted for identifying colors and/or for imaging the object 112, such as different colors of the object 112, more particularly, the color of the beacon devices 216 which might comprise different colors. The opening in the housing, which, preferably, may be located concentrically with regard to the optical axis of the detector 110, may preferably define a direction of a view of the optical detector 110.

The optical detector 110 may be adapted for determining the position of the at least one object 112. Additionally, the optical detector 110, specifically an embodiment including the camera 202, may be adapted for acquiring at least one image of the object 112, preferably a 3D-image. As outlined above, the determination of a position of the object 112 and/or a part thereof by using the optical detector 110 and/or the detector system 200 may be used for providing a human-machine interface 204, in order to provide at least one item of information to a machine 218. In the embodiments schematically depicted in FIG. 5, the machine 218 may be or may comprise at least one computer and/or a computer system comprising the data processing device 158. Other embodiments are feasible. The evaluation device 150 may be a computer 156 and/or may comprise a computer 156 and/or may fully or partially be embodied as a separate data processing device 158 and/or may fully or partially be integrated into the machine 218, particularly the computer. The same holds true for a track controller 220 of the tracking system 208, which may fully or partially form a part of the evaluation device 150 and/or the machine 218.

Similarly, as outlined above, the human-machine interface 204 may form part of the entertainment device 206. Thus, by means of the user 214 functioning as the object 112 and/or by means of the user 214 handling the object 112 and/or the control element 212 functioning as the object 112, the user 214 may input at least one item of information, such as at least one control command, into the machine 218, particularly the separate data processing device 158, thereby varying the entertainment function, such as controlling the course of a computer game.

### LIST OF REFERENCE NUMBERS

110 detector
112 object
114 longitudinal optical sensor
116 optical axis
118 housing
120 transfer device
122 refractive lens
124 opening
126 direction of view
128 coordinate system
130 sensor region
132 light beam
134 photodiode
136 illumination source
138 artificial illumination source
140 light-emitting diode
142 modulated illumination source
144 modulation device
146 first beam path
148 second beam path
150 evaluation device
152 longitudinal evaluation unit
154 signal leads
156 computer
158 data processing device
160 transversal optical sensor
162 transversal evaluation unit
164 position information
166 first electrode
168 transparent conductive oxide
170 optically transparent substrate
172 glass substrate
174 second electrode
176 metal electrode
178 thin metal layer
180 photoactive layer
182 charge-carrier blocking layer
184 charge-carrier transporting layer
186 beam path within photodiode
188 first curve
190 second curve
192 first curve
194 second curve
196 in-focus condition
198 out-of-focus condition
200 detector system
202 camera
204 human-machine interface
206 entertainment device
208 tracking system
210 imaging device
212 control element
214 user
216 beacon device
218 machine
220 track controller

1. A detector for optically detecting at least one object, comprising
at least one longitudinal optical sensor, wherein the longitudinal optical sensor has at least one sensor region, wherein the longitudinal optical sensor is designed to generate at least one longitudinal sensor signal in a manner dependent on an illumination of the sensor region by the light beam, wherein the longitudinal sensor signal, given the same total power of the illumination, is dependent on a beam cross-section of the light beam in the sensor region, wherein the longitudinal optical sensor comprises at least one photodiode, the photodiode having at least two electrodes, wherein at least one photoactive layer comprising at least one electron donor material and at least one electron acceptor material is embedded between the electrodes; and
at least one evaluation device, wherein the evaluation device is designed to generate at least one item of information on a longitudinal position of the object by evaluating the longitudinal sensor signal.

2. The detector according to claim 1, wherein the electron donor material comprises an organic donor polymer.

3. The detector according to claim 1, wherein the organic donor polymer is one of poly(3-hexylthiophene-2,5.diyl) (P3HT), poly[3-(4-n-octyl)phenylthiophene] (POPT), poly[3-10-n-octyl-3-phenothiazine-vinylenethiophene-co-2,5-thiophene] (PTZV-PT), poly[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl] (PTB7), poly{thiophene-2,5-diyl-alt-[5,6-bis(dodecyloxy)benzo[c][1,2,5]thiadiazole]-4,7-diyl} (PBT-T1), poly[2,6-(4,4-bis-(2-ethyl-hexyl)-4H-cyclopenta[2,1-b;3,4-b′]dithiophene)-alt-4,7(2,1,3-benzothiadiazole)] (PCPDTBT), poly(5,7-bis(4-decanyl-2-thienyl)-thieno(3,4-b)diathiazolethiophene-2,5) (PDDTT), poly[N-9′-heptadecanyl-2,7-carbazole-alt-5,5-(4′,7′-di-2-thienyl-2′,1′,3′-benzothia-diazole)] (PCDTBT), poly[(4,4′-bis(2-ethylhexyl)dithieno[3,2-b;2′,3′-d]silole)-2,6-diyl-alt-(2,1,3-benzothiadiazole)-4,7-diyl] (PSBTBT), poly[3-phenylhydrazone thiophene] (PPHT), poly[2-methoxy-5-(2-ethylhexyloxy)-1,4-phenylenevinylene] (MEH-PPV), poly[2-methoxy-5-(2′-ethylhexyloxy)-1,4-phenylene-1,2-ethenylene-2,5-dimethoxy-1,4- phenyene-1,2-ethenylene] (M3EH-PPV), poly[2-methoxy-5-(3′,7′-dimethyloctyloxy)-1,4-phenylene-vinylene] (MDMO-PPV), poly [9,9-di-octylfluorene-co-bis-N,N-4-butylphenyl-bis-N,N-phenyl-1,4-phenylenediamine] (PFB), or a derivative, a modification, or a mixture thereof.

4. The detector according to claim 1, wherein the electron acceptor material comprises one of a fullerene-based electron acceptor material, tetracyanoquinodimethane (TCNQ), a perylene derivative, or inorganic nanoparticles.

5. The detector according to claim 4, wherein the fullerene-based electron acceptor material comprises one of [6,6]-phenyl-C61-butric acid methyl ester (PC60BM), [6,6]-Phenyl-C71-butyric acid methyl ester (PC70BM), [6,6]-phenyl C84 butyric acid methyl ester (PC84BM), an indene-C60 bisadduct (ICBA), a diphenylmethanofullerene (DPM) moiety comprising one or two attached oligoether (OE) chains (C70-DPM-OE or C70-DPM-OE2, respectively), or a Preliminary Amendment derivative, a modification, or a mixture thereof

6. The detector according to claim 1, any one of the preceding claims, wherein the electron acceptor material comprises an organic acceptor polymer.

7. The detector according to claim 6, wherein the organic acceptor polymer comprises one of a cyano-poly[phenylenevinylene] (CN-PPV), poly[5-(2-(ethylhexyloxy)-2-methoxycyanoterephthalyliden] (MEH-CN-PPV), poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV), poly[1,4-dioctyloxyl-p-2,5-dicyanophenylenevinylene] (DOCN-PPV), poly[9,9′-di-octylfluoreneco-benzothiadiazole] (PF8BT), or a derivative, a modification, or a mixture thereof.

8. The detector according to claim 1, wherein the electron donor material and the electron acceptor material comprise an interpenetrating network of donor and acceptor domains, interfacial areas between the donor and acceptor domains, and percolation pathways connecting the domains to the electrodes.

9. The detector according to claim 1, wherein at least one of the electrodes is at least partially optically transparent.

10. (canceled)

11. The detector according to claim 9, wherein an optically transparent substrate is at least partially covered with the at least partially optically transparent electrode.

12. The detector according to claim 1, wherein at least one of the electrodes is optically intransparent and comprises a metal electrode.

13. (canceled)

14. The detector according to claim 1, wherein the photoactive layer is embedded between two different kinds of charge-influencing layers, wherein the two different kinds of charge-influencing layers comprise, for the same kind of charge carriers, a charge-carrier blocking layer and a charge-carrier transporting layer or, for two different kinds of charge carriers, two different charge-carrier blocking layers or two different charge-carrier transporting layers.

15. The detector according to claim 12, wherein at least one of the charge-influencing layer is at least partially optically transparent and is located adjacent to the at least partially optically transparent electrode.

16. The detector according to claim 12, wherein the charge-carrier blocking layer is a hole blocking layer, wherein the hole blocking layer comprises one of cesium carbonate (Cs₂CO₃), polyethylenimine (PEI), polyethylenimine ethoxylate (PEIE), 2,9-dimethyl-4,7-diphenyl-phenanthroline (BCP), (3-(4-biphenylyl)-4-phenyl-5-(4-tent-butylphenyl)-12,4-triazole) (TAZ), a transition metal oxide, or an alkaline fluoride.

17. The detector according to claim 12, wherein the charge-carrier transporting layer is a hole transporting layer, wherein the hole transporting layer is selected from the group consisting of a poly-3,4-ethylenedioxythiophene (PEDOT), a poly-aniline (PANI), a polythiophene(PT), or wherein the charge-carrier blocking layer is an electron blocking layer selected from a molybdenum oxide or a nickel oxide.

18-19. (canceled)

20. The detector according to claim 1, further comprising:
at least one transversal optical sensor, the transversal optical sensor being adapted to determine a transversal position of the light beam traveling from the object to the detector, the transversal position being a position in at least one dimension perpendicular an optical axis of the detector, the transversal optical sensor being adapted to generate at least one transversal sensor wherein the evaluation device is further designed to generate at least one item of information on a transversal position of the object by evaluating the transversal sensor signal.

21. The detector according to claim 1, wherein the detector furthermore has at least one modulation device for modulating the illumination, wherein the longitudinal optical sensor is furthermore designed in such a way that the longitudinal sensor signal, given the same total power of the illumination, is dependent on a modulation frequency of a modulation of the illumination.

22. The detector according to claim 1, furthermore comprising at least one of the group consisting of an illumination source, a transfer device, and an imaging device.

23-30. (canceled)

31. A method for an optical detection of at least one object, the method comprising:
generating at least one longitudinal sensor signal by using at least one longitudinal optical sensor , wherein the longitudinal sensor signal is dependent on an illumination of a sensor region of the longitudinal optical sensor by a light beam, wherein the longitudinal sensor signal, given the same total power of the illumination, is dependent on a beam cross-section of the light beam in the sensor region, wherein the longitudinal optical sensor comprises at least one photodiode, the photodiode having at least two electrodes, wherein at least one photoactive layer comprising at least one electron donor material and at least one electron acceptor material is embedded between the electrodes; and
evaluating the longitudinal sensor signal of the longitudinal optical sensor by determining an item of information on the longitudinal position of the object from the longitudinal sensor signal.

32. An article, comprising a detector according to claim 1, wherein the article is adapted to function as an article for an application selected from the group consisting of: a distance measurement, in particular in traffic technology; a position measurement, in particular in traffic technology; an entertainment application; a security application; a human-machine interface application; a tracking application; a logistics application; a machine vision application; a safety application; a surveillance application; a data collection application; a scanning application, a photography application; an imaging application or camera application; a mapping application for generating maps of at least one space.
